(19) United States
(12) Patent Application Publication
(10) Pub. No.: US 2025/0133918 A1
(43) Pub. Date: Apr. 24, 2025

(54) DISPLAY APPARATUS AND METHOD OF MANUFACTURING THE SAME

(71) Applicant: Samsung Display Co., Ltd., Yongin-si (KR)

(72) Inventor: Wooyong Sung, Yongin-si (KR)

(21) Appl. No.: 18/920,502

(22) Filed: Oct. 18, 2024

(30) Foreign Application Priority Data
Oct. 23, 2023 (KR) 10-2023-0142430

(51) Int. Cl. H10K 59/122; H10K 59/12; H10K 59/121; H10K 59/40; H10K 59/60; H10K 59/80

(52) U.S. Cl. CPC H10K 59/122; H10K 59/1201; H10K 59/121; H10K 59/60; H10K 59/805; H10K 59/8723; H10K 59/873; H10K 59/40

(57) ABSTRACT

A display apparatus includes a substrate including an emission area and a sensing area, a light-emitting element on the substrate and overlapping the emission area, a lower bank layer having a lower opening defining the emission area, the lower bank layer including a first conductive layer and a second conductive layer on the first conductive layer, a light-receiving element on the lower bank layer and overlapping the sensing area, and an upper bank layer including an upper opening defining the sensing area, wherein the light-emitting element and the light-receiving element are located at different layers.

### CROSS-REFERENCE TO RELATED APPLICATION

The present application claims priority to and the benefit of Korean Patent Application No. 10-2023-0142430, filed on Oct. 23, 2023, in the Korean Intellectual Property Office, the entire disclosure of which is incorporated by reference herein.

### BACKGROUND

### 1. Field

One or more embodiments relate to a display apparatus and a method of manufacturing the same.

### 2. Description of the Related Art

Display apparatuses visually display data. A display apparatus may include a substrate divided into a display area and a peripheral area. In the display area, scan lines and data lines that are insulated from each other may be formed. A plurality of pixels may be included in the display area. Additionally, the display area may include thin-film transistors respectively corresponding to the plurality of pixels and pixel electrodes respectively electrically connected to the thin-film transistors. Also, the display area may include an opposite electrode common to the plurality of pixels. The peripheral area may include various wiring lines configured to transmit electrical signals to the display area, a scan driver, a data driver, a controller, and a pad unit.

The uses of display apparatuses have diversified. Accordingly, various designs have been attempted to improve the quality of display apparatuses.

### SUMMARY

One or more embodiments provide a display apparatus capable of displaying images with excellent quality with improved resolution. Embodiments set forth herein are examples, and the scope of the present disclosure is not limited thereby.

Additional aspects will be set forth in part in the description which follows and, in part, will be apparent from the description, or may be learned by practice of the presented embodiments of the present disclosure.

According to one or more embodiments, a display apparatus includes a substrate including an emission area and a sensing area, a light-emitting element on the substrate and overlapping the emission area, a lower bank layer having a lower opening defining the emission area, the lower bank layer including a first conductive layer and a second conductive layer on the first conductive layer, a light-receiving element on the lower bank layer and overlapping the sensing area, and an upper bank layer including an upper opening defining the sensing area, wherein the light-emitting element and the light-receiving element are located at different layers.

The light-emitting element may include a pixel electrode in the emission area, an emission layer in the lower opening of the lower bank layer and overlapping the pixel electrode, and an opposite electrode in the lower opening of the lower bank layer and overlapping the emission layer.

The light-receiving element may include a sensing electrode in the sensing area, an active layer in the upper opening of the upper bank layer and overlapping the sensing electrode, and a sensing opposite electrode on the active layer and an entire surface of the substrate.

The light-emitting element and the upper bank layer overlap each other, and the light-receiving element and the lower bank layer overlap each other.

The second conductive layer may include a tip extending toward the lower opening from a point where a bottom surface of the second conductive layer and a side surface of the first conductive layer contact each other.

The lower bank layer may further include a trench between lower openings arranged adjacent to each other.

The lower bank layer may include a first portion and a second portion that are spaced from each other with the trench therebetween, wherein the first portion and the second portion may be electrically disconnected from each other.

The second portion may include a side of the lower bank layer facing the lower opening, and the first portion may be located between second portions facing different lower openings.

The second portion may be around the first portion in a plan view, and the first portion may have an island shape.

The first portion may be electrically connected to the light-receiving element, and the second portion may be electrically connected to the light-emitting element.

An opposite electrode of the light-emitting element may directly contact a side surface of the second portion facing the lower opening.

The display apparatus may further include an emission driving circuit electrically connected to the light-emitting element, and a sensing driving circuit electrically connected to the light-receiving element, wherein the emission driving circuit and the sensing driving circuit may be driven independently of each other.

The sensing driving circuit and the light-receiving element may be electrically connected to each other through the first portion.

The display apparatus may further include a bridge electrode between the sensing driving circuit and the lower bank layer, wherein a lower surface of the first conductive layer of the first portion may be in contact with the bridge electrode, and an upper surface of the second conductive layer of the first portion may be in contact with a sensing electrode of the light-receiving element.

The bridge electrode may be located at a same layer as a pixel electrode of the light-emitting element and may include a same material as the pixel electrode.

The display apparatus may further include a lower encapsulation layer covering the light-emitting element, and an upper encapsulation layer covering the light-receiving element, wherein the lower encapsulation layer and the upper encapsulation layer may be located at different layers.

The lower encapsulation layer may encapsulate the light-emitting element and may include a plurality of encapsulation layer units that are spaced from each other.

Each of the plurality of encapsulation layer units may include a first lower inorganic encapsulation layer on the light-emitting element and extending to cover the lower opening, a lower organic encapsulation layer on the first lower inorganic encapsulation layer and filling the lower opening, and a second lower inorganic encapsulation layer on the lower organic encapsulation layer.

The first lower inorganic encapsulation layer and the second lower inorganic encapsulation layer may be in contact with each other on the lower bank layer.

The upper encapsulation layer may include a first upper inorganic encapsulation layer on the light-receiving element and extending to cover the upper opening, an upper organic encapsulation layer on the first upper inorganic encapsulation layer, and a second upper inorganic encapsulation layer on the upper organic encapsulation layer.

The first upper inorganic encapsulation layer and the second upper inorganic encapsulation layer may be spaced from each other with the upper organic encapsulation layer therebetween.

The first upper inorganic encapsulation layer may be integrally formed as one body over an entire surface of the substrate.

The first upper inorganic encapsulation layer may encapsulate each of a plurality of light-receiving elements, and a plurality of first upper inorganic encapsulation layers may be spaced from each other.

The upper organic encapsulation layer may include a plurality of air cavities, wherein the plurality of air cavities may overlap the light-receiving element.

According to one or more embodiments, a method of manufacturing a display apparatus includes forming a pixel electrode on a substrate, forming a lower bank layer on the pixel electrode, the lower bank layer including a first conductive layer and a second conductive layer on the first conductive layer, forming, in the lower bank layer, a lower opening overlapping the pixel electrode, forming, in the lower opening of the lower bank layer, an emission layer overlapping the pixel electrode, forming, in the lower opening of the lower bank layer, an opposite electrode overlapping the emission layer, forming a sensing electrode on the lower bank layer, forming an upper bank layer on the sensing electrode, forming, in the upper bank layer, an upper opening overlapping the sensing electrode, forming an active layer arranged in the upper opening of the upper bank layer and overlapping the sensing electrode, and forming a sensing opposite electrode on the upper bank layer and the active layer.

The method may further include forming, in the lower bank layer, a trench between lower openings arranged adjacent to each other, wherein the trench may be formed through a same etching process as the lower opening.

The lower bank layer may include a first portion and a second portion that are spaced from each other with the trench therebetween, wherein the first portion may be in contact with the sensing electrode, and the second portion may be in contact with the opposite electrode.

The method may further include forming a lower encapsulation layer between the forming of the opposite electrode and the forming of the sensing electrode, wherein the forming of the lower encapsulation layer may include forming a first lower inorganic encapsulation layer on the opposite electrode and the lower bank layer, forming a lower organic encapsulation layer on the first lower inorganic encapsulation layer to fill the lower opening, and forming a second lower inorganic encapsulation layer on the lower organic encapsulation layer.

The method may further include, between the forming of the lower organic encapsulation layer and the forming of the second lower inorganic encapsulation layer, etching a portion of the first lower inorganic encapsulation layer on the lower bank layer, and between the forming of the second lower inorganic encapsulation layer and the forming of the sensing electrode, etching a portion of the second lower inorganic encapsulation layer on the lower bank layer.

The sensing electrode may be electrically connected to the lower bank layer through a contact hole formed by etching a portion of each of the first lower inorganic encapsulation layer and the second lower inorganic encapsulation layer.

The method may further include, after the forming of the sensing opposite electrode, forming an upper encapsulation layer, wherein the forming of the upper encapsulation layer may include forming a first upper inorganic encapsulation layer over an entire surface of the substrate on the sensing opposite electrode, forming an upper organic encapsulation layer on the first upper inorganic encapsulation layer, filling the upper opening, and on the upper bank layer, and forming a second upper inorganic encapsulation layer on the upper organic encapsulation layer.

The method may further include, between the forming of the upper organic encapsulation layer and the forming of the second upper inorganic encapsulation layer, forming a plurality of air cavities in the upper organic encapsulation layer, wherein the plurality of air cavities overlaps the sensing electrode.

The method may further include, before the forming of the pixel electrode, forming an emission driving circuit electrically connected to a light-emitting element including the pixel electrode, the emission layer, and the opposite electrode, and forming a sensing driving circuit electrically connected to a light-receiving element including the sensing electrode, the active layer, and the sensing opposite electrode.

The method may further include forming a bridge electrode between the sensing driving circuit and the lower bank layer, wherein the bridge electrode may be formed through a same deposition process as the pixel electrode.

The sensing driving circuit may be electrically connected to the sensing electrode through the bridge electrode and the lower bank layer.

### BRIEF DESCRIPTION OF DRAWINGS

The above and other aspects and features of embodiments of the present disclosure will be more apparent from the following description taken in conjunction with the accompanying drawings, in which:

FIGS. 1A and 1B are schematic perspective views of a display apparatus according to one or more embodiments;

FIGS. 2A and 2B are equivalent circuit diagrams schematically showing a light-emitting diode corresponding to one pixel of a display apparatus according to one or more embodiments and a pixel circuit electrically connected to the light-emitting diode;

FIG. 3 is a schematic cross-sectional view of a portion of a display apparatus according to one or more embodiments;

FIG. 4 is a schematic plan view of a portion of a display apparatus according to one or more embodiments;

FIG. 5 is a schematic cross-sectional view of a portion of a display apparatus according to one or more embodiments;

FIGS. 6A-6O are cross-sectional views schematically showing states according to a process of manufacturing a display apparatus according to one or more embodiments;

FIG. 7 is a schematic cross-sectional view of a portion of a display apparatus according to one or more embodiments; and

FIG. 8 is a schematic cross-sectional view of a portion of a display apparatus according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present disclosure. As used herein, the term “and/or” includes any and all combinations of one or more of the associated listed items. Throughout the present disclosure, the expression “at least one of a, b or c” indicates only a, only b, only c, both a and b, both a and c, both b and c, all of a, b, and c, or variations thereof.

The present disclosure is subject to various modifications and may have many embodiments, certain of which are illustrated in the drawings and further described in the detailed description. The effects, aspects, and features of the embodiments of the present disclosure, and methods of achieving them will become clear with reference to the embodiments described below in detail together with the drawings. However, the present disclosure is not limited to the embodiments described herein and may be implemented in various forms.

Hereinafter, embodiments will be described in detail with reference to the accompanying drawings, and when being described with reference to the drawings, the same or corresponding components are given the same reference numerals, and duplicate descriptions thereof will be omitted.

In the following embodiments, the terms first, second, etc. are not intended to be limiting, however are used to distinguish one component from another.

In the following embodiments, the singular expression includes the plural unless the context clearly indicates otherwise.

In the following embodiments, the terms including or that has, etc. are intended to imply the presence of the recited features or components and do not preclude the possibility of the addition of one or more other features or components.

In the following embodiments, when a portion of a film, area, component, etc. is over or on top of another portion, this includes not only when it is directly on top of the other portion, but also when there are other films, areas, components, etc. arranged therebetween.

In the drawings, components may be exaggerated or reduced in size for ease of illustration. For example, the size and thickness of each configuration shown in the drawings are arbitrary for purposes of illustration and the present disclosure is not necessarily limited to those shown.

In some embodiments, a particular sequence of processes may be performed in a different order than that described. For example, two processes described in succession may be performed concurrently (e.g., substantially simultaneously), or may be performed in the opposite order from the order described.

In the following embodiments, when layers, regions, or components are connected to each other, the layers, the regions, or the components may be directly connected to each other, or another layer, another region, or another component may be interposed between the layers, the regions, or the components and thus the layers, the regions, or the components may be indirectly connected to each other. For example, in the following embodiments, when layers, regions, or components are electrically connected to each other, the layers, the regions, or the components may be directly electrically connected to each other, or another layer, another region, or another component may be interposed between the layers, the regions, or the components and thus the layers, the regions, or the components may be indirectly electrically connected to each other.

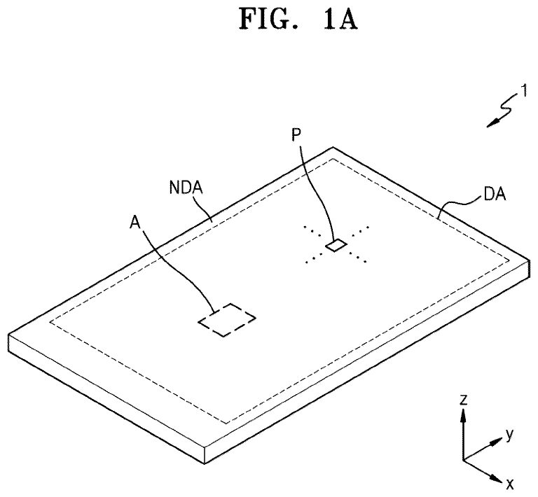

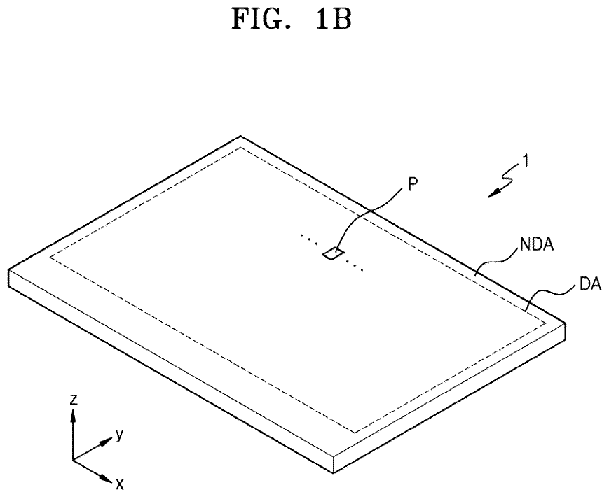

FIGS. 1A and 1B are schematic perspective views of a display apparatus 1 according to one or more embodiments.

Referring to FIGS. 1A and 1B, the display apparatus 1 may include a display area DA and a non-display area NDA arranged outside the display area DA along an edge or a periphery of the display area DA. The display area DA may display an image through a plurality of pixels P arranged in the display area DA. The non-display area NDA is arranged outside the display area DA, no image is displayed thereon, and may be around (or may entirely surround) the display area DA. Drivers for providing electrical signals or power to the display area DA and the like may be arranged in the non-display area NDA. A pad, that is, an area to which electronic elements, printed circuit boards (PCBs), or the like may be electrically connected, may be arranged in the non-display area NDA.

In one or more embodiments, although FIG. 1A illustrates that the display area DA has a polygon shape, for example, a rectangle, in which a length in an x direction is less than a length in a y direction, the present disclosure is not limited thereto. In one or more embodiments, as shown in FIG. 1B, the display area DA may have a polygon shape, for example, a rectangle, in which the length in the y direction is less than the length in the x direction. Although FIGS. 1A and 1B illustrate that the display area DA is approximately rectangular, the present disclosure is not limited thereto. In one or more embodiments, the display area DA may have various shapes, such as an N-gon shape (where N is a natural number of 3 or more), a circle, or an oval. Although FIGS. 1A and 1B illustrate that the display area DA has a shape in which a corner portion thereof includes a vertex where a straight line and another straight line meet, in another embodiment, the display area DA may have a polygon shape with a round corner portion.

In the following description, for convenience of explanation, a case in which the display apparatus 1 is a smart phone is described, but the display apparatus 1 according to one or more embodiments is not limited thereto. The display apparatus 1 may be applied to various products including not only portable electronic devices, such as mobile phones, smart phones, tablet personal computers (PCs), mobile communication terminals, electronic organizers, electronic books, portable multimedia players (PMPs), navigation devices, ultra-mobile PCs (UMPCs), and the like, but also televisions, notebook computers, monitors, billboards, internet of things (IOT), and the like. Furthermore, the display apparatus 1 according to one or more embodiments may be applied to wearable devices, such as smart watches, watch phones, glasses type displays, and head mounted displays (HMDs). Furthermore, the display apparatus 1 according to one or more embodiments may be applied to an instrument panel of a vehicle, and a center information display (CID) arranged in a center fascia or dashboard of a vehicle, a room mirror display in lieu of a side mirror of a vehicle, and a display screen arranged on the backside of the front seat as an entertainment for the rear seat of a vehicle.

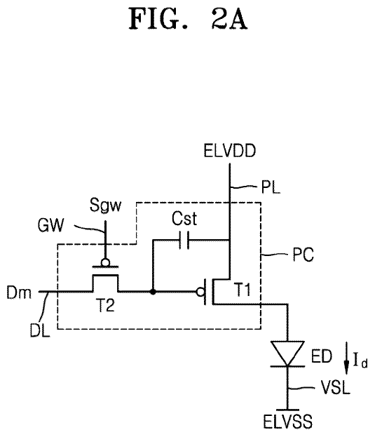

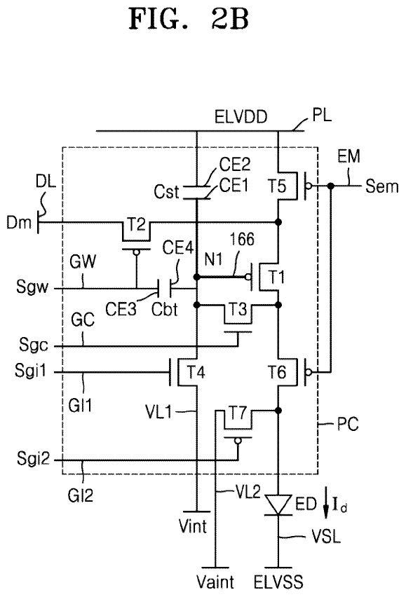

FIGS. 2A and 2B are equivalent circuit diagrams schematically showing a light-emitting diode corresponding to one pixel of a display apparatus according to one or more embodiments and a pixel circuit electrically connected to the light-emitting diode.

Referring to FIG. 2A, a light-emitting element ED may be electrically connected to a pixel circuit PC that may include a first transistor T1, a second transistor T2, and a storage capacitor Cst. A pixel electrode (e.g., an anode) of the light-emitting element ED may be electrically connected to the first transistor T1, an opposite electrode (e.g., a cathode) of the light-emitting element ED may be electrically connected to an auxiliary wiring line VSL, and a voltage corresponding to a common voltage ELVSS may be received through the auxiliary wiring line VSL.

The second transistor T2 is configured to send a data signal Dm input through a data line DL to the first transistor T1 in response to a scan signal Sgw input through a scan line GW.

The storage capacitor Cst is connected to the second transistor T2 and a driving voltage line PL, and stores a voltage corresponding to a difference between a voltage received from the second transistor T2 and a driving voltage ELVDD supplied through the driving voltage line PL.

The first transistor T1 is connected to the driving voltage line PL, the storage capacitor Cst, and the light-emitting element ED, and may be configured to control a driving current Id flowing in the light-emitting element ED from the driving voltage line PL, corresponding to a voltage value stored in the storage capacitor Cst. The light-emitting element ED may emit light having a certain brightness by the driving current Id.

Although FIG. 2A illustrates a case in which the pixel circuit PC includes two transistors and one storage capacitor, the present disclosure is not limited thereto.

Referring to FIG. 2B, the pixel circuit PC may include seven transistors and two capacitors.

The pixel circuit PC may include first to seventh transistors T1, T2, T3, T4, T5, T6, and T7, a storage capacitor Cst, and a boost capacitor Cbt. In another embodiment, the pixel circuit PC may not include the boost capacitor Cbt. A pixel electrode (e.g., an anode) of a light-emitting element ED may be electrically connected to the first transistor T1 via the sixth transistor T6, an opposite electrode (e.g., a cathode) may be connected to an auxiliary wiring line VSL, and a voltage corresponding to a common voltage ELVSS may be received through the auxiliary wiring line VSL.

Some of the first to seventh transistors T1, T2, T3, T4, T5, T6, and T7 may be n-channel MOSFETs (NMOS), and the remaining transistors may be p-channel MOSFETs (PMOS). In one or more embodiments, as shown in FIG. 2B, the third and fourth transistors T3 and T4 may be n-channel MOSFETs (NMOS), and the remaining transistors may be p-channel MOSFETs (PMOS). For example, the third and fourth transistors T3 and T4 may be n-channel MOSFETs (NMOS) including an oxide-based semiconductor material, and the remaining transistors may be p-channel MOSFETs (PMOS) including a silicon-based semiconductor material. In another embodiment, the third, fourth, and seventh transistors T3, T4, and T7 may be n-channel MOSFETs (NMOS), and the remaining transistors may be p-channel MOSFETs (PMOS).

The first to seventh transistors T1, T2, T3, T4, T5, T6, and T7, the storage capacitor Cst, and the boost capacitor Cbt may be connected to a signal line. The signal line may include a scan line GW, an emission control line EM, a compensation gate line GC, a first initialization gate line GI1, a second initialization gate line GI2, and a data line DL. The pixel circuit PC may be electrically connected to a voltage line, for example, the driving voltage line PL, a first initialization voltage line VL1, and a second initialization voltage line VL2.

The first transistor T1 may be a drive transistor. A first gate electrode of the first transistor T1 is connected to the storage capacitor Cst, a first electrode of the first transistor T1 is electrically connected to the driving voltage line PL via the fifth transistor T5, and a second electrode of the first transistor T1 may be electrically connected to a pixel electrode (for example, an anode) of the light-emitting element ED via the sixth transistor T6. One of the first electrode and the second electrode of the first transistor T1 may be a source electrode, and the other may be a drain electrode. The first transistor T1 may be configured to supply the driving current Id to the light-emitting element ED according to a switching operation of the second transistor T2.

The second transistor T2 may be a switching transistor. A second gate electrode of the second transistor T2 is connected to the scan line GW, a first electrode of the second transistor T2 is connected to the data line DL, and a second electrode of the second transistor T2 is connected to the first electrode of the first transistor T1 and electrically connected to the driving voltage line PL via the fifth transistor T5. One of the first electrode and the second electrode of the second transistor T2 may be a source electrode, and the other may be a drain electrode. The second transistor T2 may be configured to be turned on in response to the scan signal Sgw received through the scan line GW and to perform a switching operation of sending the data signal Dm sent through the data line DL to the first electrode of the first transistor T1.

The third transistor T3 may be a compensation transistor for compensating a threshold voltage of the first transistor T1. A third gate electrode of the third transistor T3 is connected to the compensation gate line GC. A first electrode of the third transistor T3 is connected to a lower electrode CE1 of the storage capacitor Cst and a first gate electrode of the first transistor T1 through a node connection line 166. The first electrode of the third transistor T3 may be connected to the fourth transistor T4. A second electrode of the third transistor T3 is connected to the second electrode of the first transistor T1 and electrically connected to the pixel electrode (for example, an anode) of the light-emitting element ED via the sixth transistor T6. One of the first electrode and the second electrode of the third transistor T3 may be a source electrode, and the other may be a drain electrode.

The third transistor T3 may be configured to turned on in response to a compensation signal Sgc received through the compensation gate line GC and electrically connect the first gate electrode and the second electrode (for example, a drain electrode) of the first transistor T1 to each other, thereby diode-connecting the first transistor T1 (e.g., the first transistor T1 may be diode-connected).

The fourth transistor T4 may be a first initialization transistor to initialize the first gate electrode of the first transistor T1. A fourth gate electrode of the fourth transistor T4 is connected to the first initialization gate line GI1. A first electrode of the fourth transistor T4 is connected to the first initialization voltage line VL1. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode, and the other may be a drain electrode. The fourth transistor T4 may be configured to turned on in response to a first initialization signal Sgi1 received through the first initialization gate line GI1 and send a first initialization voltage Vint to the first gate electrode of the first transistor T1, thereby performing an initialization operation to initialize the voltage of the first gate electrode of the first transistor T1.

The fifth transistor T5 may be an operation control transistor. A fifth gate electrode of the fifth transistor T5 is connected to the emission control line EM, a first electrode of the fifth transistor T5 is connected to the driving voltage line PL, and a second electrode of the fifth transistor T5 is connected to the first electrode of the first transistor T1 and the second electrode of the second transistor T2. One of the first electrode and the second electrode of the fifth transistor T5 may be a source electrode, and the other may be a drain electrode.

The sixth transistor T6 may be an emission control transistor. A sixth gate electrode of the sixth transistor T6 is connected to the emission control line EM, a first electrode of the sixth transistor T6 is connected to the second electrode of the first transistor T1 and the second electrode of the third transistor T3, and a second electrode of the sixth transistor T6 is electrically connected to a second electrode of the seventh transistor T7 and the pixel electrode (for example, an anode) of the light-emitting element ED. One of the first electrode and the second electrode of the sixth transistor T6 may be a source electrode, and the other may be a drain electrode.

The fifth transistor T5 and the sixth transistor T6 may be configured to be concurrently (e.g., simultaneously) turned on in response to an emission control signal Sem received through the emission control line EM and send the driving voltage ELVDD to the light-emitting element ED, thereby allowing the driving current Id to flow in the light-emitting element ED.

The seventh transistor T7 may be a second initialization transistor that initialize the pixel electrode (for example, an anode) of the light-emitting element ED. A seventh gate electrode of the seventh transistor T7 is connected to the second initialization gate line GI2. A first electrode of the seventh transistor T7 is connected to the second initialization voltage line VL2. A second electrode of the seventh transistor T7 is connected to the second electrode of the sixth transistor T6 and the pixel electrode (for example, an anode) of the light-emitting element ED. The seventh transistor T7 may be configured to be turned on in response to a second initialization signal Sgi2 received through the second initialization gate line GI2 and send a second initialization voltage Vaint to the pixel electrode (for example, an anode) of the light-emitting element ED, thereby initializing the pixel electrode of the light-emitting element ED.

In one or more embodiments, the second initialization gate line GI2 may serve as a subsequent scan line. For example, the second initialization gate line GI2 connected to the seventh transistor T7 of the pixel circuit PC arranged in the i-th row, where “i” is a natural number, may correspond to a scan line of the pixel circuit PC arranged in the (i+1)th row. In one or more embodiments, the second initialization gate line GI2 may serve as the emission control line EM. For example, the emission control line EM may be electrically connected to the fifth to seventh transistors T5, T6, and T7.

The storage capacitor Cst may include the lower electrode CE1 and an upper electrode CE2. The lower electrode CE1 of the storage capacitor Cst is connected to the first gate electrode of the first transistor T1, and the upper electrode CE2 of the storage capacitor Cst is connected to the driving voltage line PL. The storage capacitor Cst may store electric charges corresponding to a difference between the voltage of the first gate electrode of the first transistor T1 and the driving voltage ELVDD.

The boost capacitor Cbt may include a third electrode CE3 and a fourth electrode CE4. The third electrode CE3 is connected to the second gate electrode of the second transistor T2 and the scan line GW, and the fourth electrode CE4 may be connected to the first electrode of the third transistor T3 and the node connection line 166. The boost capacitor Cbt may increase a voltage of a first node N1 when the scan signal Sgw supplied through the scan line GW is turn off, and when the voltage of the first node N1 is increased, black gradation may be clearly expressed.

The first node N1 may be an area where the first gate electrode of the first transistor T1, the first electrode of the third transistor T3, the second electrode of the fourth transistor T4, and the fourth electrode CE4 of the boost capacitor Cbt are connected to one another.

In one or more embodiments, FIG. 2B illustrates that the third and fourth transistors T3 and T4 are n-channel MOSFETs (NMOS), and the first, second, fifth, sixth, and seventh transistors T1, T2, T5, T6, and T7 are p-channel MOSFETs (PMOS). The first transistor T1 that directly affects the brightness of a display apparatus for displaying an image is configured to include a semiconductor layer including polycrystalline silicon having high reliability, and accordingly, a high-resolution display apparatus may be implemented.

Although FIG. 2B illustrates that some transistors are n-channel MOSFETs (NMOS) and the remaining transistors are p-channel MOSFETs (PMOS), the present disclosure is not limited thereto. In one or more embodiments, the pixel circuit PC may include three transistors and the three transistors may all be n-channel MOSFETs (NMOS).

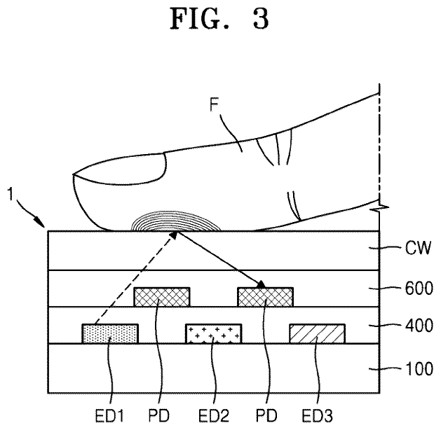

FIG. 3 is a schematic cross-sectional view of a portion of a display apparatus 1 according to one or more embodiments.

Referring to FIG. 3, the display apparatus 1 according to one or more embodiments may include a first light-emitting element ED1, a second light-emitting element ED2, a third light-emitting element ED3, and a light-receiving element PD. The first light-emitting element ED1, the second light-emitting element ED2, and the third light-emitting element ED3 may emit different color lights. For example, the first light-emitting element ED1 may emit red light, the second light-emitting element ED2 may emit green light, and the third light-emitting element ED3 may emit blue light.

As shown in FIG. 3, the display apparatus 1 may have a function of sensing an object in contact with a cover window CW, for example, a fingerprint of a finger F. Of light emitted from at least one of the first light-emitting element ED1, the second light-emitting element ED2, and the third light-emitting element ED3, at least a portion of the reflected light reflected from the user's fingerprint may be re-incident to the light-receiving element PD, and thus, the light-receiving element PD may detect the reflected light. For example, the red light emitted by the first light-emitting element ED1 may be reflected by an object in contact with the cover window CW and re-incident to the light-receiving element PD, and thus, the light-receiving element PD may detect re-incident red light.

The first to third light-emitting elements ED1, ED2, and ED3 and the light-receiving element PD may be disposed on (e.g., at) different layers. In one or more embodiments, the first light-emitting element ED1, the second light-emitting element ED2, and the third light-emitting element ED3 may be disposed on a substrate 100, and the first to third light-emitting elements ED1, ED2, and ED3 may be encapsulated with a lower encapsulation layer 400. A plurality of light-receiving elements PD may be disposed on the flattened upper surface of the lower encapsulation layer 400, and the plurality of light-receiving elements PD may be encapsulated with an upper encapsulation layer 600. When the first to third light-emitting elements ED1, ED2, and ED3 and the light-receiving element PD are disposed on (e.g., at) different layers as shown in FIG. 3, an emission area of each of the first to third light-emitting elements ED1, ED2, and ED3 may be increased, and thus, the resolution of the display apparatus 1 may be improved.

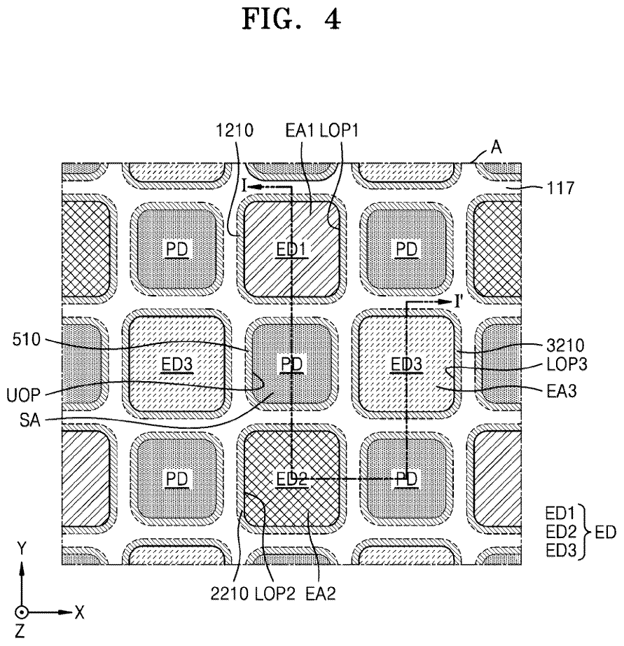

FIG. 4 is a schematic plan view of a portion of a display apparatus according to one or more embodiments. Specifically, FIG. 4 is an enlarged plan view of an area A in FIG. 1A. FIG. 4 shows a plan view on an upper bank layer 117 for convenience.

Referring to FIG. 4, the display apparatus may include a plurality of light-emitting elements and a plurality of light-receiving elements PD. The plurality of light-emitting elements may include a first light-emitting element ED1, a second light-emitting element ED2, and a third light-emitting element ED3, and the first light-emitting element ED1, the second light-emitting element ED2, and the third light-emitting element ED3 may emit light of different colors. For example, the first light-emitting element ED1 may emit red light, the second light-emitting element ED2 may emit green light, and the third light-emitting element ED3 may emit blue light. Red light may be light belonging to a wavelength band of about 600 nm to about 780 nm, green light may be light belonging to a wavelength band of about 495 nm to about 600 nm, and blue light may be light belonging to a wavelength band of about 380 nm to about 495 nm. In one or more embodiments, the light-receiving element PD may sense an object by detecting light emitted from the first light-emitting element ED1, the second light-emitting element ED2, and the third light-emitting element ED3 and reflected by the object. In one or more embodiments, the light-receiving element PD may sense an object by detecting light emitted from a near-infrared light-emitting unit and reflected by the object.

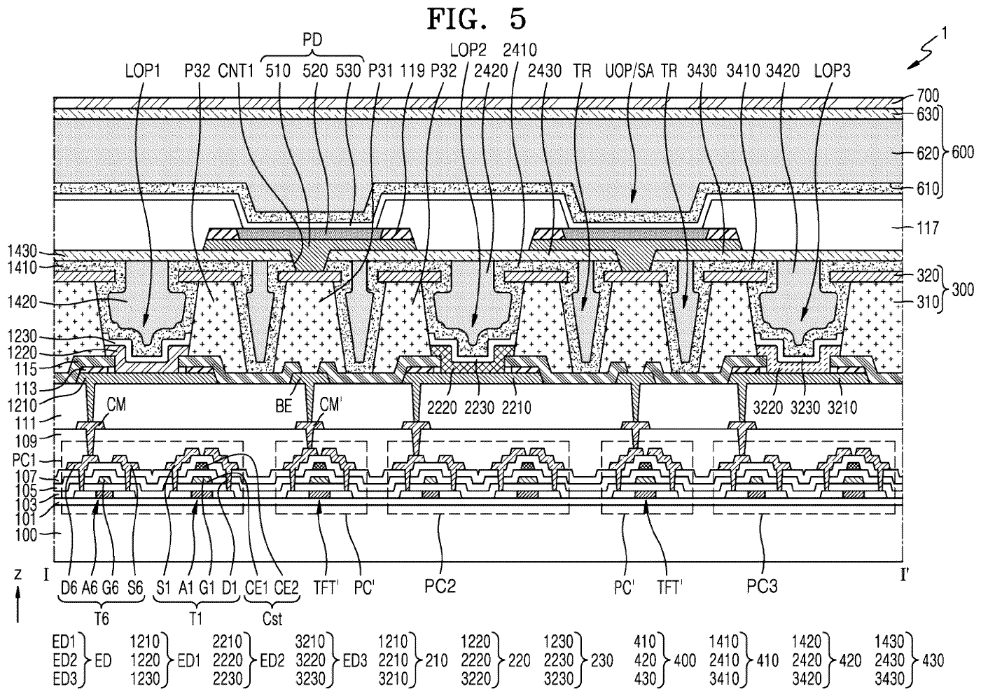

Each light-emitting element ED may include a pixel electrode, an opposite electrode, and an emission layer disposed therebetween, and each light-receiving element PD may include a sensing electrode, a sensing opposite electrode, and an active layer disposed therebetween. Accordingly, the first light-emitting element ED1 may include a first pixel electrode 1210, the second light-emitting element ED2 may include a second pixel electrode 2210, the third light-emitting element ED3 may include a third pixel electrode 3210, and the light-receiving element PD may include a sensing electrode 510. The first to third pixel electrodes 1210, 2210, and 3210 and the sensing electrode 510 may be arranged to be spaced from each other on a substrate 100 (see FIG. 5). In this specification, “in a plan view” means a plan viewed in a direction perpendicular to the substrate 100. That is, “A and B that are spaced from each other in a plan view” means “A and B that are spaced from each other when viewed in a direction perpendicular to the substrate 100.”

A bank layer may be disposed on the first to third pixel electrodes 1210, 2210, and 3210 or the sensing electrode 510, and may cover the edge of each of the first to third pixel electrodes 1210, 2210, and 3210 or the edge of the sensing electrode 510. However, in one or more embodiments, the bank layer may include a double bank layer including a lower bank layer 300 (see FIG. 5) and an upper bank layer 117 (see FIG. 5). As previously described with reference to FIG. 3, when the light-emitting element ED and the light-receiving element PD are disposed on different layers, the lower bank layer 300 may be disposed above the first to third pixel electrodes 1210, 2210, and 3210 and the upper bank layer 117 may be disposed above the sensing electrode 510. That is, the lower bank layer 300 may have a first lower opening LOP1 exposing a central portion of the first pixel electrode 1210, a second lower opening LOP2 exposing a central portion of the second pixel electrode 2210, and a third lower opening LOP3 exposing a central portion of the third pixel electrode 3210. Similarly, the upper bank layer 117 may have an upper opening UOP that exposes a central portion of the sensing electrode 510.

Although not shown in FIG. 4, emission layers that emit light may be located in the first to third lower openings LOP1, LOP2, and LOP3 of the lower bank layer 300, respectively, and active layers that detect light may be located in the upper opening UOP of the upper bank layer 117. The opposite electrode may be disposed on the emission layers, and the sensing opposite electrode may be disposed on the active layers. As described above, a structure in which the pixel electrode, the emission layer, and the opposite electrode are stacked may form one light-emitting element ED. Additionally, as described above, a stacked structure including the sensing electrode, the active layer, and the sensing opposite electrode may form one light-receiving element PD. One opening in the lower bank layer 300 corresponds to one light-emitting element ED and may define one emission area. Alternatively, one opening of the upper bank layer 117 may correspond to one light-receiving element PD and define one sensing area SA.

For example, an emission layer that emits red light may be arranged in the first lower opening LOP1, and the first lower opening LOP1 may define a first emission area EA1. Similarly, an emission layer that emits green light may be arranged in the second lower opening LOP2, and the second lower opening LOP2 may define a second emission area EA2. An emission layer that emits blue light may be arranged in the third lower opening LOP3, and the third lower opening LOP3 may define a third emission area EA3. An active layer for detecting light may be arranged in the upper opening UOP, and the upper opening UOP may define a sensing area SA.

Accordingly, the size of the area of the first lower opening LOP1 is the same as the size of the area of the first emission area EA1. In addition, the size of the area of the second lower opening LOP2 is the same as the size of the area of the second emission area EA2, and the size of the area of the third lower opening LOP3 is the same as the size of the area of the third emission area EA3. The size of the area of the upper opening UOP is the same as the size of the area of the sensing area SA.

Each of the first to third lower openings LOP1, LOP2, and LOP3 and the upper opening UOP may have a polygonal shape when viewed in a direction (z-direction) perpendicular to the substrate 100 (see FIG. 5). In other words, each of the first to third emission areas EA1, EA2, and EA3 and the sensing area SA may have a polygonal shape when viewed in the direction (z-direction) perpendicular to the substrate 100. FIG. 4 illustrates that each of the first to third emission areas EA1, EA2, and EA3 and the sensing area SA has a quadrangular shape, specifically, a quadrangular shape having round corners, when viewed in the direction (z-direction) perpendicular to the substrate 100. However, the present disclosure is not limited thereto. For example, each of the first to third emission areas EA1, EA2, and EA3 and the sensing area SA may have a circular or oval shape when viewed in the direction (z-direction) perpendicular to the substrate 100.

FIG. 5 is a schematic cross-sectional view of a portion of a display apparatus 1 taken along the line I-I′ of FIG. 4, according to one or more embodiments.

Referring to FIG. 5, the display apparatus 1 may include a light-emitting element ED, an emission driving circuit (i.e., first to third emission driving circuits PC1, PC2, and PC3) electrically connected to the light-emitting element ED, a light-receiving element PD, and a sensing driving circuit PC′ electrically connected to the light-receiving device PD. First, the emission driving circuit and the sensing driving circuit PC′ may be formed on the substrate 100. The emission driving circuit may include a first emission driving circuit PC1 connected to the first light-emitting element ED1, a second emission driving circuit PC2 connected to the second light-emitting element ED2, and a third emission driving circuit PC3 connected to the third light-emitting element ED3. The first emission driving circuit PC1, the second emission driving circuit PC2, the third emission driving circuit PC3, and the sensing driving circuit PC′ may have the same structure. However, the first to third emission driving circuits PC1, PC2, and PC3 and the sensing driving circuit PC′ may be driven independently of each other. The first to third emission driving circuits PC1, PC2, and PC3 and the sensing driving circuit PC′ may each include a transistor and a storage capacitor as previously described with reference to FIGS. 2A and 2B. In one or more embodiments, FIG. 5 shows a first transistor T1, a sixth transistor T6, and a storage capacitor Cst of each of the first to third emission driving circuits PC1, PC2, and PC3, and shows a transistor TFT′ of each sensing driving circuit PC′.

The substrate 100 may include glass or polymer resin. The substrate 100 may include a structure in which a base layer including a polymer resin and an inorganic barrier layer are stacked. The polymer resin may include polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate, cellulose triacetate (TAC), and/or cellulose acetate propionate (CAP).

A buffer layer 101 may be disposed on an upper surface of the substrate 100. The buffer layer 101 may prevent impurities from infiltrating into a semiconductor layer of a transistor. The buffer layer 101 may include an inorganic insulating material, such as silicon nitride, silicon oxynitride, and/or silicon oxide, and may be a single layer or multilayer including the aforementioned inorganic insulating material.

The first transistor T1 may include a first semiconductor layer A1 on the buffer layer 101 and a first gate electrode G1 overlapping a channel region of the first semiconductor layer A1 in the z-direction. The first semiconductor layer A1 may include a silicon-based semiconductor material, for example, polysilicon. The first semiconductor layer A1 may include the channel region and a first region and a second region disposed on both sides of the channel region. The first region and the second region are regions including impurities having a higher concentration than that of the channel region, and any one of the first region and the second region may correspond to a source region and the other may correspond to a drain region.

The sixth transistor T6 may include a sixth semiconductor layer A6 on the buffer layer 101 and a sixth gate electrode G6 overlapping the channel region of the sixth semiconductor layer A6 in the z-direction. The sixth semiconductor layer A6 may include a silicon-based semiconductor material, for example, polysilicon. The sixth semiconductor layer A6 may include a channel region, and a first region and a second region arranged in both sides of the channel region. The first region and the second region are regions including impurities having a higher concentration than that of the channel region, and any one of the first region and the second region may correspond to a source region and the other may correspond to a drain region.

The first gate electrode G1 and the sixth gate electrode G6 may each include a conductive material including molybdenum (Mo), aluminum (Al), copper (Cu), titanium (Ti), or the like, and may have a single-layered or multi-layered structure including the aforementioned material. A first gate insulating layer 103 for electrical insulation from the first semiconductor layer A1 and the sixth semiconductor layer A6 may be arranged below the first gate electrode G1 and the sixth gate electrode G6 covering the buffer layer 101 and the semiconductor layers. The first gate insulating layer 103 may include an inorganic insulating material, such as silicon nitride, silicon oxynitride, and/or silicon oxide, and may be a single layer or multilayer including the aforementioned inorganic insulating material.

The storage capacitor Cst may include the lower electrode CE1 and the upper electrode CE2 overlapping each other in the z-direction. In one or more embodiments, the lower electrode CE1 of the storage capacitor Cst may include the first gate electrode G1. In other words, the first gate electrode G1 may include the lower electrode CE1 of the storage capacitor Cst. For example, the first gate electrode G1 and the lower electrode CE1 of the storage capacitor Cst may be integrally formed.

A first interlayer insulating layer 105 may be arranged between the lower electrode CE1 and the upper electrode CE2 of the storage capacitor Cst, and may cover the first gate insulating layer 103 and the gate electrodes. The first interlayer insulating layer 105 may include an inorganic insulating material, such as silicon oxide, silicon nitride, and/or silicon oxynitride, and may have a single-layered or multi-layered structure including the aforementioned inorganic insulating material.

The upper electrode CE2 of the storage capacitor Cst may include a low-resistance conductive material, such as Mo, Al, Cu, and/or Ti, and may have a single-layered or multi-layered structure including the aforementioned material.

A second interlayer insulating layer 107 may be arranged between the upper electrode CE2 of the storage capacitor Cst and a source electrode S1, and may cover the first interlayer insulating layer 105 and the upper electrode CE2 of the storage capacitor Cst. The second interlayer insulating layer 107 may include an inorganic insulating material, such as silicon oxide, silicon nitride, and/or silicon oxynitride, and may have a single-layered or multi-layered structure including the aforementioned inorganic insulating material.

A source electrode S1 and/or a drain electrode D1 electrically connected to the first semiconductor layer A1 of the first transistor T1 may be disposed on the second interlayer insulating layer 107. A source electrode S6 and/or a drain electrode

D6 electrically connected to the sixth semiconductor layer A6 of the sixth transistor T6 may be disposed on the second interlayer insulating layer 107. The source electrodes S1 and S6 and/or the drain electrodes D1 and D6 may each include Al, Cu, and/or Ti, and may be in a single layer or multilayer including the aforementioned material.

A first organic insulating layer 109 may be disposed on the emission driving circuits PC1, PC2, and PC3 and the sensing driving circuit PC′. The first organic insulating layer 109 may include an organic insulating material, such as acryl, benzocyclobutene (BCB), polyimide, hexamethyldisiloxane (HMDSO), and/or the like.

Connection metals CM and CM′ may be disposed on the first organic insulating layer 109. The connection metals CM and CM′ may include Al, Cu, and/or Ti, and may be in a single layer or multilayer including the aforementioned material.

A second organic insulating layer 111 may be arranged between the connection metals CM and CM′ and the pixel electrode 210 (210: 1210, 2210, and 3210). The second organic insulating layer 111 may include an organic insulating material, such as acryl, BCB, polyimide, HMDSO, and/or the like. According to the embodiment described with reference to FIG. 5, the emission driving circuits PC1, PC2, and PC3 and the pixel electrode 210 are electrically connected to each other through the connection metal CM. However, according to one or more embodiments, the connection metal CM may be omitted, and one organic insulating layer may be located between the emission driving circuits PC1, PC2, and PC3 and the pixel electrode 210. Alternatively, three or more organic insulating layers may be located between the emission driving circuits PC1, PC2, and PC3 and the pixel electrode 210, and the emission driving circuits PC1, PC2, and PC3 and the pixel electrode 210 may be connected to each other through a plurality of connection metals. Additionally, these embodiments may be equally applied to the connection metal CM′ that electrically connects the sensing driving circuit PC′ to a bridge electrode BE to be described later.

Each of the first to third light-emitting elements ED1, ED2, and ED3 electrically connected to the first to third emission driving circuits PC1, PC2, and PC3, respectively may have a structure in which a pixel electrode 210, an emission layer 220, and an opposite electrode 230 are stacked.

For example, the first light-emitting element ED1 may include a first pixel electrode 1210, a first emission layer 1220, and a first opposite electrode 1230. The first pixel electrode 1210 may be electrically connected to the first emission driving circuit PC1. The second light-emitting element ED2 may include a second pixel electrode 2210, a second emission layer 2220, and a second opposite electrode 2230. The second pixel electrode 2210 may be electrically connected to the second emission driving circuit PC2. The third light-emitting element ED3 may include a third pixel electrode 3210, a third emission layer 3220, and a third opposite electrode 3230. The third pixel electrode 3210 may be electrically connected to the third emission driving circuit PC3.

The pixel electrode 210 may be formed on the second organic insulating layer 111. The pixel electrode 210 may be a (semi-)transparent electrode or a reflective electrode. When the pixel electrode 210 is a (semi-)transparent electrode, the pixel electrode 210 may include, for example, indium tin oxide (ITO), indium zinc oxide (IZO), zinc oxide (ZnO), indium oxide (In₂O₃), indium gallium oxide (IGO), and/or aluminum zinc oxide (AZO). When the pixel electrode 210 is a reflective electrode, the pixel electrode 210 may include a reflective layer formed of Ag, Mg, Al, Pt, Pd, Au, Ni, Nd, Ir, Cr, or a compound thereof, and a layer including ITO, IZO, ZnO, and/or In₂O₃ may be formed on the reflective layer. In one or more embodiments, the pixel electrode 210 may have a structure in which an ITO layer, an Ag layer, and an ITO layer are sequentially stacked. The pixel electrode 210 may be electrically connected to the connection metal CM through a contact hole in the second organic insulating layer 111.

A bridge electrode BE that electrically connects the sensing driving circuit PC′ to the light-receiving element PD may also be formed on the second organic insulating layer 111. The bridge electrode BE may be disposed on (e.g., at) the same layer as the pixel electrode 210 and may include the same material as the pixel electrode 210. In one or more embodiments, the bridge electrode BE may have a structure in which an ITO layer, an Ag layer, and an ITO layer are sequentially stacked. The bridge electrode BE may be electrically connected to the connection metal CM′ through a contact hole in the second organic insulating layer 111.

An insulating layer 115 may be formed on the pixel electrode 210 and the bridge electrode BE. The insulating layer 115 may be disposed on the pixel electrode 210 and the bridge electrode BE to cover an outer portion of each of the pixel electrode 210 and the bridge electrode BE. For example, the insulating layer 115 may overlap the pixel electrode 210 and may be in direct contact with the upper surface of the second organic insulating layer 111 where the pixel electrode 210 is not present. The insulating layer 115 may cover the side surface of each of the pixel electrode 210 and the bridge electrode BE. The insulating layer 115 may include an inorganic insulating material. When the insulating layer 115 includes an inorganic insulating material, deterioration in the quality of a light-emitting diode due to gas emitted from an insulating layer, which includes an organic insulating material, during a process of manufacturing the display apparatus may be prevented or reduced, compared to the case where the insulating layer 115 includes an organic insulating material.

The insulating layer 115 may include an inorganic insulating material, such as silicon oxide, silicon nitride, and/or silicon oxynitride, and may have a single-layered or multi-layered structure including the aforementioned inorganic insulating material. In one or more embodiments, the insulating layer 115 may have a two-layered structure including a silicon oxide layer and a silicon nitride layer. The thickness of the silicon oxide layer may be less than the thickness of the silicon nitride layer.

The insulating layer 115 may be arranged to be around (e.g., to surround) the first to third pixel electrodes 1210, 2210, and 3210 and the bridge electrode BE. Specifically, the insulating layer 115 may surround the pixel electrode 210 while including an opening exposing a central portion of the pixel electrode 210. Similarly, the insulating layer 115 may be around (e.g., may surround) the bridge electrode BE while including openings exposing a central portion of the bridge electrode BE.

A first protective layer 113 may be formed between the pixel electrode 210 and the insulating layer 115. The first protective layer 113 may be deposited to overlap the pixel electrode 210, but may then be etched to expose the central portion of the pixel electrode 210, thereby leaving only a portion of the first protective layer 113. The first protective layer 113 may prevent the pixel electrode 210 from being damaged by gas or liquid substances used in various etching processes or ashing processes included in a process of manufacturing the display apparatus 1. The first protective layer 113 may include a conductive oxide, such as ITO, IZO, indium gallium zinc oxide (IGZO), indium tin zinc oxide (ITZO), ZnO, aluminum doped zinc oxide (AZO), gallium doped zinc oxide (GZO), zinc tin oxide (ZTO), gallium tin oxide (GTO), and/or fluorine doped tin oxide (FTO).

A lower bank layer 300 may be disposed on the insulating layer 115. The lower bank layer 300 may include a first conductive layer 310 and a second conductive layer 320 on the first conductive layer 310. The first conductive layer 310 and the second conductive layer 320 include a conductive material and may include different metals. For example, the first conductive layer 310 and the second conductive layer 320 may include metals having different etch selectivities. In one or more embodiments, the first conductive layer 310 may be a layer including Al, and the second conductive layer 320 may be a layer including Ti.

The thickness of the first conductive layer 310 may be greater than the thickness of the second conductive layer 320. In one or more embodiments, the thickness of the first conductive layer 310 may be approximately 5 times greater than the thickness of the second conductive layer 320. For example, the first conductive layer 310 may have a thickness of about 4000 Å to about 8000 Å, and the second conductive layer 320 may have a thickness of about 500 Å to about 800 Å.

The lower bank layer 300 may have first to third lower openings LOP1, LOP2, and LOP3 overlapping the first to third pixel electrodes 1210, 2210, and 3210, respectively. Each of the first to third lower openings LOP1, LOP2, and LOP3 may pass through from the top surface of the lower bank layer 300 to the bottom surface thereof, and may have an undercut cross-sectional structure. The side of the first conductive layer 310 facing a corresponding opening from among the first to third lower openings LOP1, LOP2, and LOP3 of the lower bank layer 300 may have a forward tapered shape and may have an inclination angle that is equal to or greater than about 60° and less than about 90°. The second conductive layer 320 of the lower bank layer 300 may include a portion protruding toward a lower opening. Specifically, the second conductive layer 320 may include a tip extending from a point, at which the bottom surface of the second conductive layer 320 and the side surface of the first conductive layer 310 contact each other, toward a corresponding one of the first to third lower openings LOP1, LOP2, and LOP3.

In the display apparatus 1 according to one or more embodiments, the emission layer 220 (220: 1220, 2220, 3220) and the opposite electrode 230 (230: 1230, 2230, 3230) may be deposited without using a separate mask due to the structure of the lower bank layer 300 including the first to third lower openings LOP1, LOP2, and LOP3 having an undercut structure. Therefore, damage to the display apparatus 1 caused by a mask may be prevented, and resolution may be increased because an area for placing the mask is not required.

Specifically, the emission layer 220 and the opposite electrode 230 may be arranged in the first to third lower openings LOP1, LOP2, and LOP3 to overlap the pixel electrode 210. The emission layer 220 may overlap and contact an inner portion of the pixel electrode 210, and the opposite electrode 230 may overlap the emission layer 220. The structure in which the pixel electrode 210, the emission layer 220, and the opposite electrode 230 are stacked corresponds to the light-emitting element ED that is a light-emitting diode (LED). The emission layer 220 may include a first emission layer 1220 arranged in the first lower opening LOP1, a second emission layer 2220 arranged in the second lower opening LOP2, and a third emission layer 3220 arranged in the third lower opening LOP3. The opposite electrode 230 may include a first opposite electrode 1230 disposed on the first emission layer 1220, a second opposite electrode 2230 disposed on the second emission layer 2220, and a third opposite electrode 3230 disposed on the third emission layer 3220.

The emission layer 220 may include a polymer or low-molecular organic material that emits light having a certain color (red, green, or blue). In one or more embodiments, the emission layer 220 may include an inorganic material or quantum dots. In this case, the first emission layer 1220, the second emission layer 2220, and the third emission layer 3220 may emit light of different colors. The emission layer 220 may have a single stack structure including a single emission layer or a tandem structure that is a multi-stack structure including a plurality of emission layers.

The emission layer 220 may overlap the pixel electrode 210 through the first to third lower openings LOP1, LOP2, and LOP3 of the lower bank layer 300. Accordingly, the width of the emission area of the light-emitting element ED may be substantially the same as the widths of the first to third lower openings LOP1, LOP2, and LOP3.

The opposite electrode 230 may include a conductive material having a low

work function. For example, the opposite electrode 230 may include a transparent layer (e.g., a semi-transparent layer) including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and/or an alloy thereof. Alternatively, the opposite electrode 230 may further include a transparent conductive oxide (TCO) layer, such as an ITO, IZO, ZnO, and/or In₂O₃ layer, on the transparent layer (e.g., a semi-transparent layer) including the aforementioned material.

The first opposite electrode 1230 arranged in the first lower opening LOP1, the second opposite electrode 2230 arranged in the second lower opening LOP2, and the third opposite electrode 3230 arranged in the third lower opening LOP3 may be spatially separated or spaced from each other. The first opposite electrode 1230, the second opposite electrode 2230, and the third opposite electrode 3230 may be electrically connected to each other and may have the same voltage level. For example, the first opposite electrode 1230, the second opposite electrode 2230, and the third opposite electrode 3230 may each have the same voltage level as a voltage (e.g., common voltage) provided by an auxiliary wiring line VSL. Each of the first to third opposite electrodes 1230, 2230, and 3230 may be electrically connected to the auxiliary wiring line VSL through the lower bank layer 300.

For example, an outer portion of the first opposite electrode 1230 may be electrically connected to (e.g., directly contact) the side of the lower bank layer 300 (e.g., the side of the first conductive layer 310) facing the first lower opening LOP1, and as the lower bank layer 300 is electrically connected to a portion of the auxiliary wiring line VSL, the first opposite electrode 1230 may receive the common voltage. Similarly, an outer portion of the second opposite electrode 2230 and an outer portion of the third opposite electrode 3230 may also directly contact the side of the lower bank layer 300 facing the second lower opening LOP2 and the third lower opening LOP3, respectively, and as the lower bank layer 300 is electrically connected to a portion of the auxiliary wiring line VSL, the second opposite electrode 2230 and the third opposite electrode 3230 may also receive the common voltage.

In one or more embodiments, a common layer may be arranged between the pixel electrode 210 and the emission layer 220 and/or between the emission layer 220 and the opposite electrode 230. Specifically, a first common layer may be arranged between the pixel electrode 210 and the emission layer 220, and a second common layer may be arranged between the emission layer 220 and the opposite electrode 230. The first common layer may include a hole transport layer (HTL) and/or a hole injection layer (HIL). The second common layer may include an electron transport layer (ETL) and/or an electron injection layer (EIL). The first common layer and the second common layer may each include an organic material.

In addition, in one or more embodiments, because the emission layer 220 and the opposite electrode 230 are deposited in the first to third lower openings LOP1, LOP2, and LOP3 by the undercut structure of the lower bank layer 300 without a mask, the emission layer 220 and the opposite electrode 230 may be partially deposited on the lower bank layer 300. For example, a deposition material for forming the emission layer 220 and a deposition material for forming the opposite electrode 230 may be used to form a dummy emission layer and a dummy opposite electrode on the lower bank layer 300. The emission layer 220 and the dummy emission layer may include the same material and may be separated and be spaced from each other, and the opposite electrode 230 and the dummy opposite electrode may include the same material and may be separated and spaced from each other.

The lower bank layer 300 may further include a trench TR in addition to the first to third lower openings LOP1, LOP2, and LOP3. The trench TR may be arranged between lower openings arranged adjacent to each other. For example, the trench TR may be arranged between the first lower opening LOP1 and the second lower opening LOP2 or between the second lower opening LOP2 and the third lower opening LOP3. In other words, the trench TR may be arranged between light-emitting elements ED arranged adjacent to each other.

The trench TR may have a shape that passes through the lower bank layer 300, similar to the first to third lower openings LOP1, LOP2, and LOP3. The trench TR may have a concave shape with respect to the upper surface of the lower bank layer 300. Additionally, the trench TR may have an undercut shape, similar to the first to third lower openings LOP1, LOP2, and LOP3. A portion of the second conductive layer 320 of the lower bank layer 300 may include a tip protruding toward the trench TR. Because the trench TR may be formed by etching the first conductive layer 310 and the second conductive layer 320, the trench TR may expose the insulating layer 115. That is, the bottom surface of the trench TR may be substantially the same as the top surface of the insulating layer 115.

The lower bank layer 300 may be divided into a first portion P31 and a second portion P32 by the trench TR formed by etching a portion of the lower bank layer 300. The first portion P31 and the second portion P32 of the lower bank layer 300 may be arranged to be spaced from each other with the trench TR therebetween. Because the first portion P31 and the second portion P32 are separated and spaced from each other, the first portion P31 and the second portion P32 may not be electrically connected to each other.

The second portion P32 may be a portion including a side of the lower bank layer 300 facing a corresponding lower opening from among the first to third lower openings LOP1, LOP2, and LOP3 of the lower bank layer 300. The first portion P31 may be arranged between second portions P32 facing different lower openings. For example, in a cross-sectional view in a direction perpendicular to the substrate 100, the first portion P31 may be arranged between a second portion P32 adjacent to the first lower opening LOP1 and a second portion P32 adjacent to the second lower opening LOP2. Additionally, the trench TR and the second portion P32 may have a shape that is around (e.g., that surrounds) the first portion P31 in a plan view. In this case, the first portion P31 may have an island shape.

As described above, the lower bank layer 300 may transmit a common voltage to the opposite electrode 230. Because the opposite electrode 230 is in direct contact with the side of the second portion P32 of the lower bank layer 300, the lower bank layer 300 that transmits a voltage to the opposite electrode 230 may be the second portion P32. In other words, the second portion P32 of the lower bank layer 300 may be connected to the auxiliary wiring line VSL (see FIG. 2A) and may transmit the common voltage to the opposite electrode 230.

Because the first portion P31, which is spaced from the second portion P32 by the trench TR, is not electrically connected to the second portion P32, the first portion P31 may transmit another electrical signal to the light-receiving element PD. In other words, the first portion P31 may be electrically connected to the light-receiving element PD, and the second portion P32 may be electrically connected to the light-emitting element ED.

Specifically, the first portion P31 may function as a connection electrode that electrically connects the sensing driving circuit PC′ to the light-receiving element PD. Because the first portion P31 includes the first conductive layer 310 and the second conductive layer 320 each including a conductive material, the first portion P31 may function as a connection electrode that transmits a signal, unlike the bank layer (or pixel-defining layer) that generally includes an inorganic or organic insulating material. Specifically, the lower surface of the first conductive layer 310 of the first portion P31 may be in direct contact with the bridge electrode BE connected to the sensing driving circuit PC′, and the upper surface of the second conductive layer 320 of the first portion P31 may be in contact with a sensing electrode 510 through a contact hole CNT1. Accordingly, a signal output from the sensing driving circuit PC′ may be transmitted to the sensing electrode 510 of the light-receiving element PD through the bridge electrode BE and the first portion P31.

The first to third light-emitting elements ED1, ED2, and ED3 may be

encapsulated by a lower encapsulation layer 400. The lower encapsulation layer 400 may include at least one inorganic encapsulation layer and at least one organic encapsulation layer. For example, the lower encapsulation layer 400 may include a first lower inorganic encapsulation layer 410 (410: 1410, 2410, 3210), a lower organic encapsulation layer 420 (420: 1420, 2420, 3420) on the first lower inorganic encapsulation layer 410, and a second lower inorganic encapsulation layer 430 (430: 1430, 2430, 3430) on the lower organic encapsulation layer 420.

The first lower inorganic encapsulation layer 410 and the second lower inorganic encapsulation layer 430 may include one or more inorganic materials selected from aluminum oxide, titanium oxide, tantalum oxide, hafnium oxide, zinc oxide, silicon oxide, silicon nitride, and/or silicon oxynitride. The first lower inorganic encapsulation layer 410 and the second lower inorganic encapsulation layer 430 may each include a single layer or multilayer including the aforementioned material. The lower organic encapsulation layer 420 may include a polymer-based material. Examples of the polymer-based material may include acrylic resin, epoxy resin, polyimide, and polyethylene. In one or more embodiments, the lower organic encapsulation layer 420 may include acrylate. The lower organic encapsulation layer 420 may be formed by curing a monomer or applying a polymer. The lower organic encapsulation layer 420 may be transparent.

The first lower inorganic encapsulation layer 410, which has relatively excellent step coverage, may cover at least a portion of the inner surface of each of the first to third lower openings LOP1, LOP2, and LOP3 of the lower bank layer 300 having the undercut structure, and at least a portion of the inner surface of the trench TR. For example, the first lower inorganic encapsulation layer 410 may be continuously formed to overlap the upper and side surfaces of the lower bank layer 300 and the upper surface of the opposite electrode 230. The lower organic encapsulation layer 420 may be located on the first lower inorganic encapsulation layer 410 and may fill at least a portion of each of the first to third lower openings LOP1, LOP2, and LOP3 of the lower bank layer 300, and at least a portion of the inner surface of the trench TR. The second lower inorganic encapsulation layer 430 may be disposed on the lower organic encapsulation layer 420.

In one or more embodiments, the lower encapsulation layer 400 may encapsulate each of the light-emitting elements ED and may include a plurality of encapsulation layer units arranged to be spaced from each other. Specifically, the lower encapsulation layer 400 may include a first encapsulation layer unit that encapsulates the first light-emitting element ED1, a second encapsulation layer unit that encapsulates the second light-emitting element ED2, and a third encapsulation layer unit that encapsulates the third light-emitting element ED3.

For example, the first encapsulation layer unit may include a 1st-1 lower inorganic encapsulation layer 1410 covering the first light-emitting element ED1, a first lower organic encapsulation layer 1420 filling the first lower opening LOP1, and a 2nd-1 lower inorganic encapsulation layer 1430 on the first lower organic encapsulation layer 1420. The second encapsulation layer unit may include a 1st-2 lower inorganic encapsulation layer 2410 covering the second light-emitting element ED2, a second lower organic encapsulation layer 2420 filling the second lower opening LOP2, and a 2nd-2 lower inorganic encapsulation layer 2430 on the second lower organic encapsulation layer 2420. The third encapsulation layer unit may include a 1st-3 lower inorganic encapsulation layer 3410 covering the third light-emitting element ED3, a third lower organic encapsulation layer 3420 filling the third lower opening LOP3, and a 2nd-3 lower inorganic encapsulation layer 3430 on the third lower organic encapsulation layer 3420.

The first encapsulation layer unit, the second encapsulation layer unit, and the third encapsulation layer unit may be arranged to be spaced from each other due to the contact hole CNT1 formed on the lower bank layer 300. The contact hole CNT1 may be a contact hole formed in layers arranged between the lower bank layer 300 and the sensing electrode 510 to connect the sensing driving circuit PC′ to the sensing electrode 510. Specifically, the first lower inorganic encapsulation layer 410 and the second lower inorganic encapsulation layer 430 may be separated from each other by etching portions thereof to form the contact hole CNT1. For example, the first lower inorganic encapsulation layer 410 may include a 1st-1 lower inorganic encapsulation layer 1410, a 1st-2 lower inorganic encapsulation layer 2410, and a 1st-3 lower inorganic encapsulation layer 3410, which are separated from each other by the contact hole CNT1. Similarly, the second lower inorganic encapsulation layer 430 may include a 2nd-1 lower inorganic encapsulation layer 1430, a 2nd-2 lower inorganic encapsulation layer 2430, and a 2nd-3 lower inorganic encapsulation layers 3430, which are separated from each other by the contact hole CNT1.

The lower organic encapsulation layer 420 may not be formed on the lower bank layer 300, but may be formed to fill only the first to third lower openings LOP1, LOP2, and LOP3, and at least a portion of the inner surface of the trench TR. Accordingly, the first lower inorganic encapsulation layer 410 and the second lower inorganic encapsulation layer 430 may be in direct contact with each other on the lower bank layer 300.

Because the lower encapsulation layer 400 having the above structure that includes a plurality of encapsulation layer units spaced from each other, a structure in which each light-emitting element ED is sealed for each pixel unit may be formed. Because the lower encapsulation layer 400 may seal each light-emitting element ED, even when a defect, such as a dark spot, occurs due to penetration of contaminants from the outside, the effect of suppressing the growth of the defect may be provided. Accordingly, the display apparatus 1 according to one or more embodiments may improve resolution by using the lower bank layer 300 having the undercut structure, and may produce excellent quality images by sealing each light-emitting element ED.

Referring back to FIG. 5, the light-receiving element PD may be disposed on the lower encapsulation layer 400. As previously described, the light-emitting element ED and the light-receiving element PD may be disposed on (e.g., at) different layers.

As the light-receiving element PD is arranged to overlap the lower bank layer 300, which is a non-emission area, an emission area may be secured and resolution may be improved. The light-receiving element PD may have a structure in which a sensing electrode 510, an active layer 520, and a sensing opposite electrode 530 may be stacked.

The sensing electrode 510 may be disposed on the second lower inorganic encapsulation layer 430. The sensing electrode 510 may be arranged to overlap the lower bank layer 300 and not overlap the emission area of the light-emitting element ED. The sensing electrode 510 may be connected to the first portion P31 of the lower bank layer 300 through the contact hole CNT1 passing through the first lower inorganic encapsulation layer 410 and the second lower inorganic encapsulation layer 430. Accordingly, the light-receiving element PD may be connected to the sensing driving circuit PC′ through the first portion P31 and receive a signal.

The sensing electrode 510 may include the same material as the pixel electrode 210. The sensing electrode 510 may be a transparent electrode, a semi-transparent, electrode or a reflective electrode. When the sensing electrode 510 is a transparent electrode or a semi-transparent electrode, the sensing electrode 510 may include, for example, ITO, IZO, ZnO, In₂O₃, IGO, and/or AZO. When the sensing electrode 510 is a reflective electrode, the sensing electrode 510 may include a reflective layer formed of Ag, Mg, Al, Pt, Pd, Au, Ni, Nd, Ir, Cr, and/or a compound thereof, and a layer including ITO, IZO, ZnO, and/or In₂O₃ may be formed on the reflective layer. In one or more embodiments, the sensing electrode 510 may have a structure in which an ITO layer, an Ag layer, and an ITO layer are sequentially stacked.

An upper bank layer 117 may be formed on the sensing electrode 510. The upper bank layer 117 may be disposed on the sensing electrode 510 to cover an outer portion of the sensing electrode 510. For example, the upper bank layer 117 may overlap the sensing electrode 510 and may be in direct contact with the upper surface of the second lower inorganic encapsulation layer 430 where the sensing electrode 510 is not present. The upper bank layer 117 may cover the side surface of the sensing electrode 510.

The upper bank layer 117 may be arranged to be around (e.g., to surround) the sensing electrode 510. Specifically, the upper bank layer 117 may include an upper opening UOP that exposes a central portion of the sensing electrode 510 and covers the edges of the sensing electrode 510. The upper opening UOP may pass from the top surface of the upper bank layer 117 to the bottom surface thereof, and the side surface of the upper bank layer 117 may have a forward tapered shape. The upper opening UOP may define a sensing area SA.

The upper bank layer 117 may include an inorganic insulating layer and/or an organic insulating layer. In one or more embodiments, when the upper bank layer 117 includes an inorganic insulating layer, the upper bank layer 117 may include the same material as the insulating layer 115. For example, the upper bank layer 117 may include an inorganic insulating material, such as silicon oxide, silicon nitride, and/or silicon oxynitride, and may have a single-layered or multi-layered structure including the aforementioned inorganic insulating material. In one or more embodiments, the upper bank layer 117 may have a two-layered structure including a silicon oxide layer and a silicon nitride layer. In one or more embodiments, when the upper bank layer 117 includes an organic insulating layer, the upper bank layer 117 may include an organic insulating layer, such as polyimide, polyamide, acrylic resin, benzocyclobutene, hexamethyldisiloxane (HMDSO), and/or phenolic resin.

A second protective layer 119 may be formed between the sensing electrode 510 and the upper bank layer 117. The second protective layer 119 may be deposited to overlap the sensing electrode 510, but may then be etched to expose a central portion of the sensing electrode 510, thereby leaving only a portion of the second protective layer 119. The second protective layer 119 may prevent the sensing electrode 510 from being damaged by gas or liquid substances used in various etching processes or ashing processes included in a process of manufacturing the display apparatus 1. The second protective layer 119 may include a conductive oxide, such as ITO, IZO, IGZO, ITZO, ZnO, AZO, GZO, ZTO, GTO, and/or FTO.

The active layer 520 may be arranged in the upper opening UOP of the upper bank layer 117 to overlap the sensing electrode 510. The active layer 520 may include a p-type organic semiconductor and an n-type organic semiconductor. In this case, the p-type organic semiconductor may act as an electron donor, and the n-type organic semiconductor may act as an electron acceptor.

In one or more embodiments, the active layer 520 may be a mixed layer in which a p-type organic semiconductor and an n-type organic semiconductor are mixed. In this case, the active layer 520 may be formed by co-depositing a p-type organic semiconductor and an n-type organic semiconductor. When the active layer 520 is a mixed layer, excitons may be generated within a diffusion length from a donor-acceptor interface.

In one or more embodiments, the p-type organic semiconductor may be a compound that acts as an electron donor to supply electrons. For example, the p-type organic semiconductor may include, but is not limited to, boron subphthalocyanine chloride (SubPc), copper(II) phthalocyanine (CuPc), tetraphenyldibenzoferiplanthene (DBP), and/or any combination thereof.

In one or more embodiments, the n-type organic semiconductor may be a compound that acts as an electron acceptor to accept electrons. For example, the n-type organic semiconductor may include, but is not limited to, C60 fullerene, C70 fullerene, or any combination thereof.

The active layer 520 may receive light from the outside to generate excitons and then separate the generated excitons into holes and electrons. When a (+) potential is applied to the sensing electrode 510 and a (−) potential is applied to the sensing opposite electrode 530, holes separated within the active layer 520 may move toward the sensing opposite electrode 530, and electrons separated within the active layer 520 may move toward the sensing electrode 510. Accordingly, a photocurrent may be formed in a direction from the sensing electrode 510 to the sensing opposite electrode 530.

When a bias is applied between the sensing electrode 510 and the sensing opposite electrode 530, a dark current may flow in the light-receiving element PD. Additionally, when light is incident on the light-receiving element PD, a photocurrent may flow in the light-receiving element PD. In one or more embodiments, the light-receiving element PD may detect the amount of light from the ratio of the photocurrent to the dark current.

The sensing opposite electrode 530 may be disposed on the active layer 520 to overlap the active layer 520. However, the sensing opposite electrode 530 may not only be arranged in the upper opening UOP, but may also be formed continuously on the upper bank layer 117. That is, the sensing opposite electrode 530 may be formed over the entire surface of the substrate and integrally formed as one body. In one or more embodiments, the sensing opposite electrode 530 may include the same material as the opposite electrode 230. The sensing opposite electrode 530 may be a transparent or translucent electrode, and may include a transparent layer or a semi-transparent layer including Ag, Mg, Al, Pt, Pd, Au, Ni, Nd, Ir, Cr, Li, Ca, and/or an alloy thereof. Alternatively, the sensing opposite electrode 530 may further include a TCO layer, such as an ITO, IZO, ZnO, and/or In₂O₃ layer, on the transparent layer or the semi-transparent layer including the aforementioned material.

In one or more embodiments, a common layer may be arranged between the sensing electrode 510 and the active layer 520 and/or between the active layer 520 and the sensing opposite electrode 530. Specifically, a first common layer may be arranged between the sensing electrode 510 and the active layer 520, and a second common layer may be arranged between the active layer 520 and the sensing opposite electrode 530. The first common layer may include an HTL and/or an HIL. The second common layer may include an ETL and/or an EIL. The first common layer and the second common layer may each include an organic material.

Through the structure of the light-receiving element PD as described above, the display apparatus 1 according to one or more embodiments may further improve resolution. When the light-emitting element ED and the light-receiving element PD are disposed on (e.g., at) the same layer, a separate area where the light-receiving element PD may be disposed in addition to the light-emitting element ED has to be secured on the same plane, and thus, the emission area of the light-emitting element ED may be relatively reduced. On the other hand, in the display apparatus 1 as shown in FIG. 5, the light-receiving element PD is not only disposed on a different layer from the light-emitting element ED, but also the light-receiving element PD is disposed above the lower bank layer 300, which is a non-emission area, and accordingly, the resolution may be significantly improved by efficiently utilizing space. In addition, because the light-receiving element PD may receive signals from the sensing driving circuit PC′ by using the lower bank layer 300 including a conductive material, there is no need to separately arrange signal transmission wiring lines, and thus, it is easier to secure an emission area and improve resolution.

The light-receiving element PD may be encapsulated by an upper encapsulation layer 600. The upper encapsulation layer 600 may include at least one inorganic encapsulation layer and at least one organic encapsulation layer. For example, the upper encapsulation layer 600 may include a first upper inorganic encapsulation layer 610, an upper organic encapsulation layer 620 on the first upper inorganic encapsulation layer 610, and a second upper inorganic encapsulation layer 630 on the upper organic encapsulation layer 620.

The first upper inorganic encapsulation layer 610 and the second upper inorganic encapsulation layer 630 may include one or more inorganic materials selected from aluminum oxide, titanium oxide, tantalum oxide, hafnium oxide, zinc oxide, silicon oxide, silicon nitride, and/or silicon oxynitride. The first upper inorganic encapsulation layer 610 and the second upper inorganic encapsulation layer 630 may each include a single layer or multilayer including the aforementioned material. The upper organic encapsulation layer 620 may include a polymer-based material. Examples of the polymer-based material may include acrylic resin, epoxy resin, polyimide, and/or polyethylene. In one or more embodiments, the upper organic encapsulation layer 620 may include acrylate. The upper organic encapsulation layer 620 may be formed by curing a monomer or applying a polymer. The upper organic encapsulation layer 620 may be transparent.

The first upper inorganic encapsulation layer 610, which has relatively excellent step coverage, may cover at least a portion of the inner surface of the upper opening UOP of the upper bank layer 117. For example, the first upper inorganic encapsulation layer 610 may be continuously formed to overlap the upper and side surfaces of the upper bank layer 117 and the upper surface of the sensing opposite electrode 530. However, the first upper inorganic encapsulation layer 610 may cover not only the upper opening UOP but also the upper surface of the upper bank layer 117. That is, the first upper inorganic encapsulation layer 610 may be integrally formed as one body over the entire surface of the substrate 100. The upper organic encapsulation layer 620 may be located on the first upper inorganic encapsulation layer 610, fill the upper opening UOP, and may be also formed on the upper bank layer 117 to flatten the upper surface of the display apparatus 1. The second upper inorganic encapsulation layer 630 may be disposed on the upper organic encapsulation layer 620. Accordingly, the first upper inorganic encapsulation layer 610 and the second upper inorganic encapsulation layer 630 may be arranged to be spaced from each other with the upper organic encapsulation layer 620 therebetween.

An input sensing layer 700 may be disposed on the upper encapsulation layer 600. The input sensing layer 700 may acquire coordinate information according to an external input, for example, a touch event. The input sensing layer 700 may include a plurality of touch electrodes and a touch insulating layer.

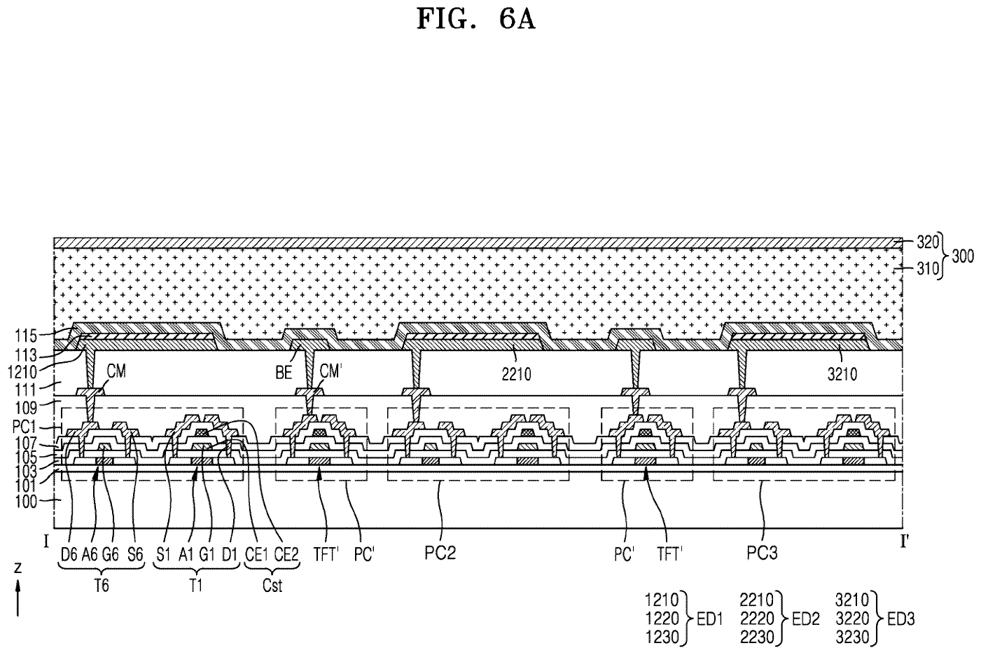

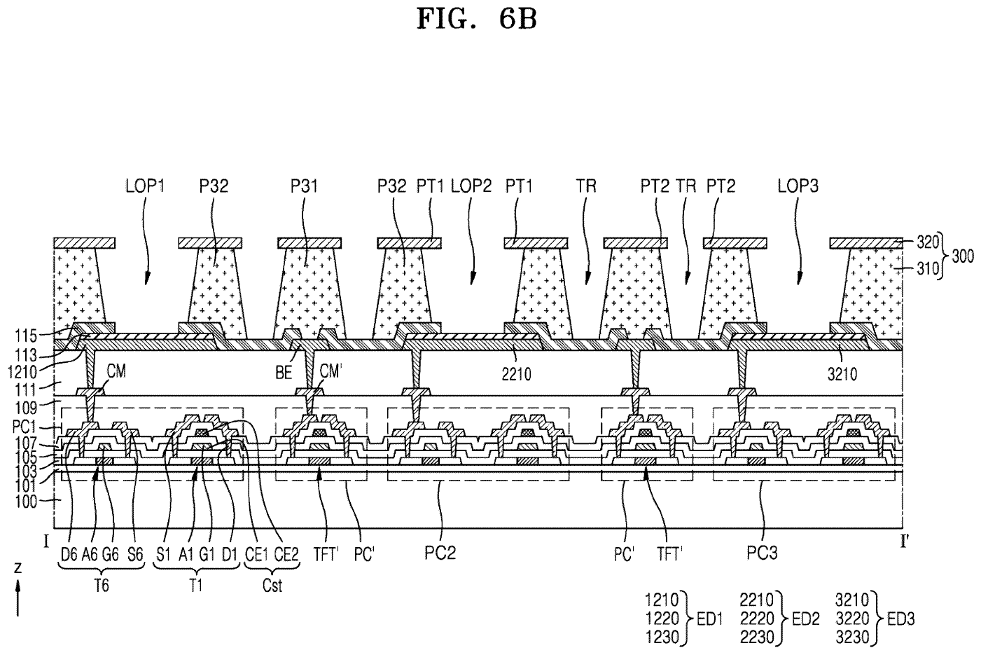

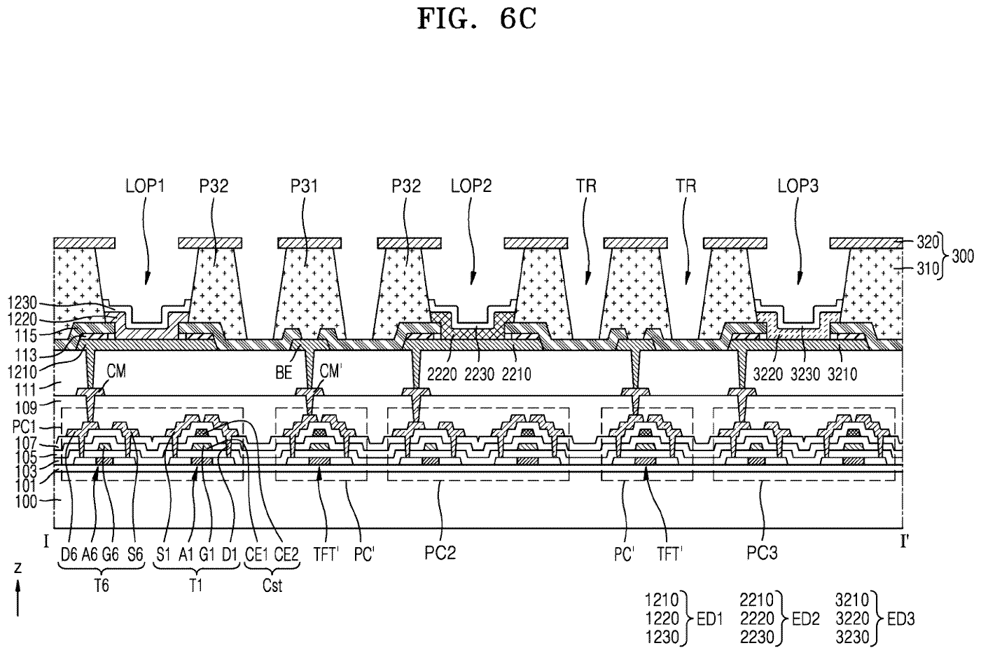

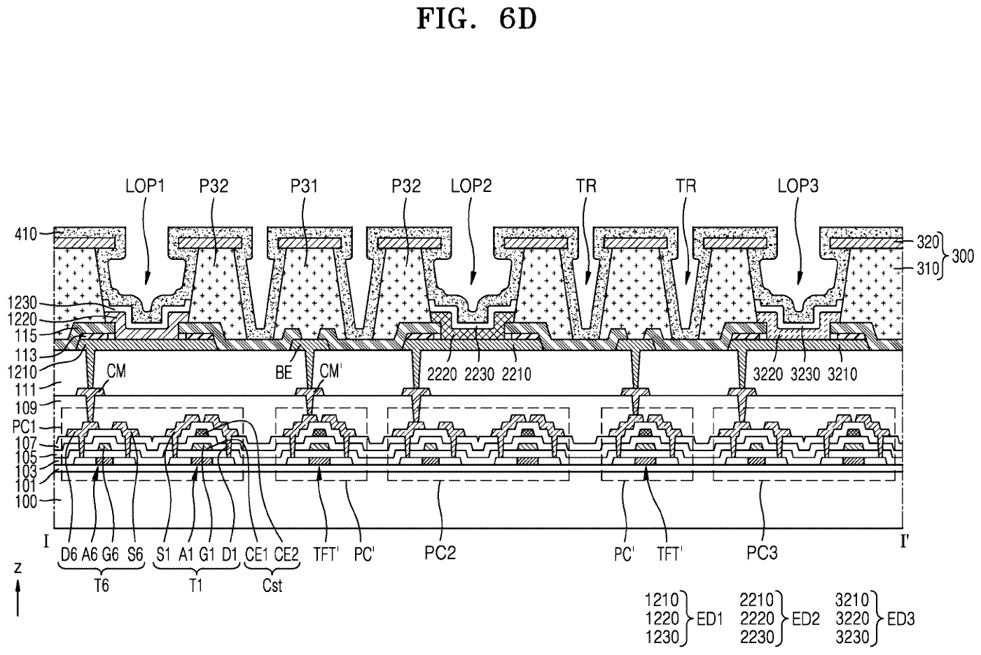

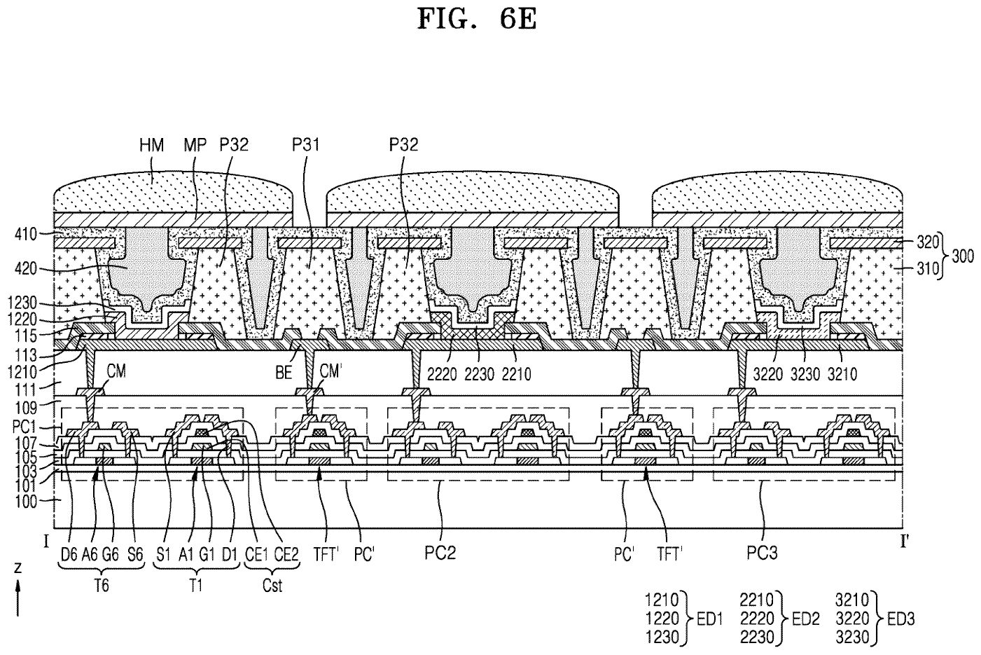

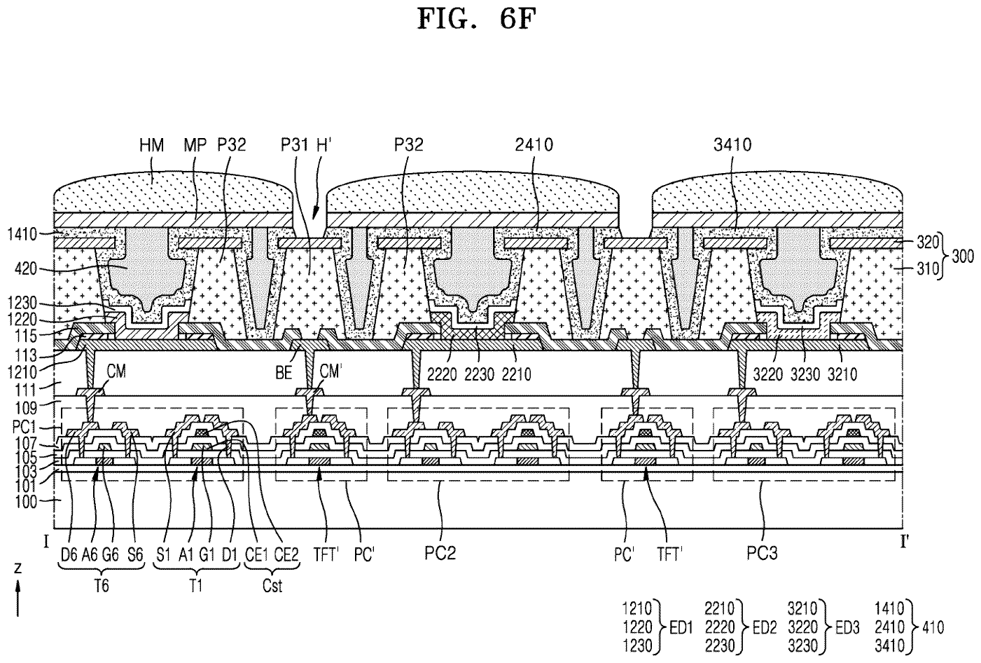

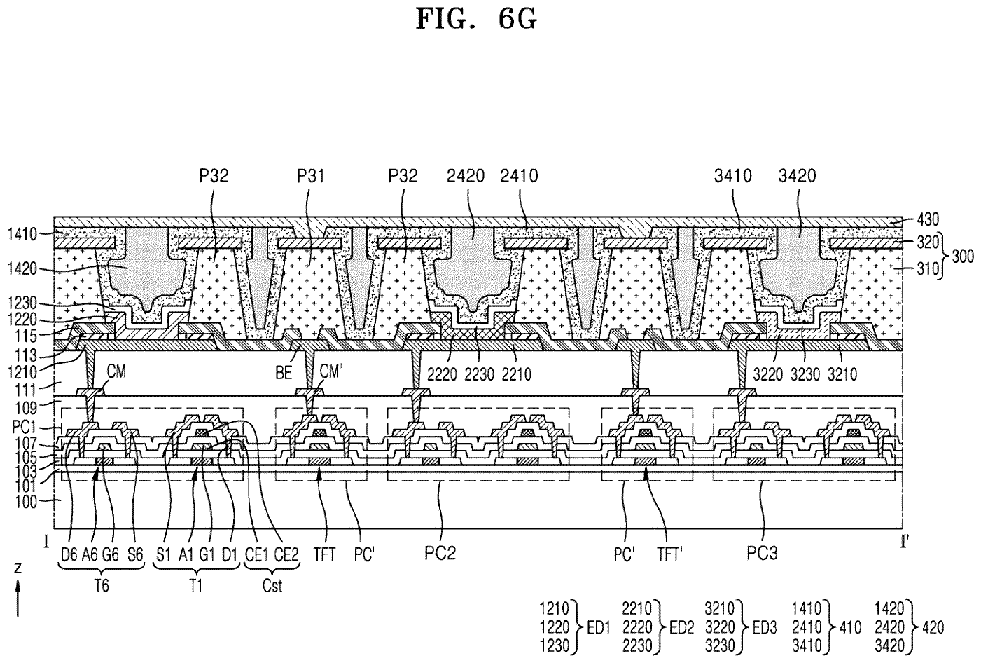

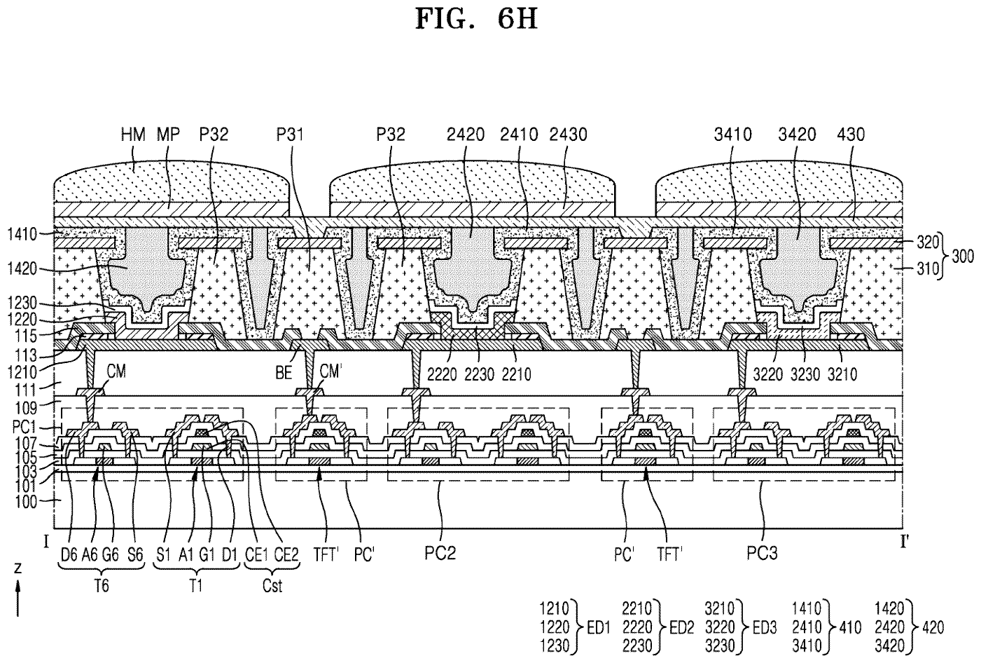

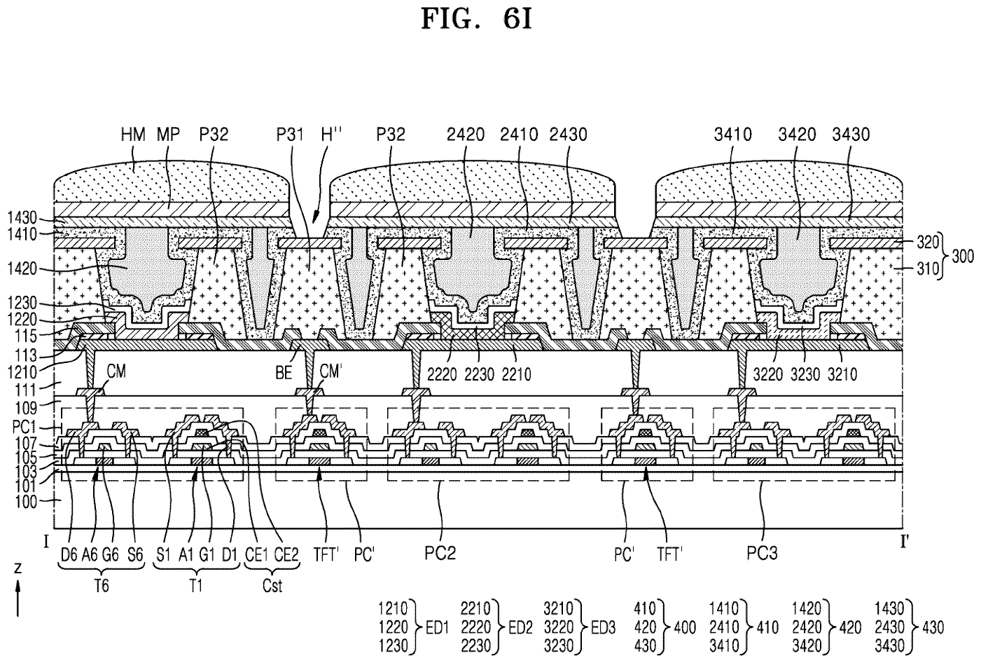

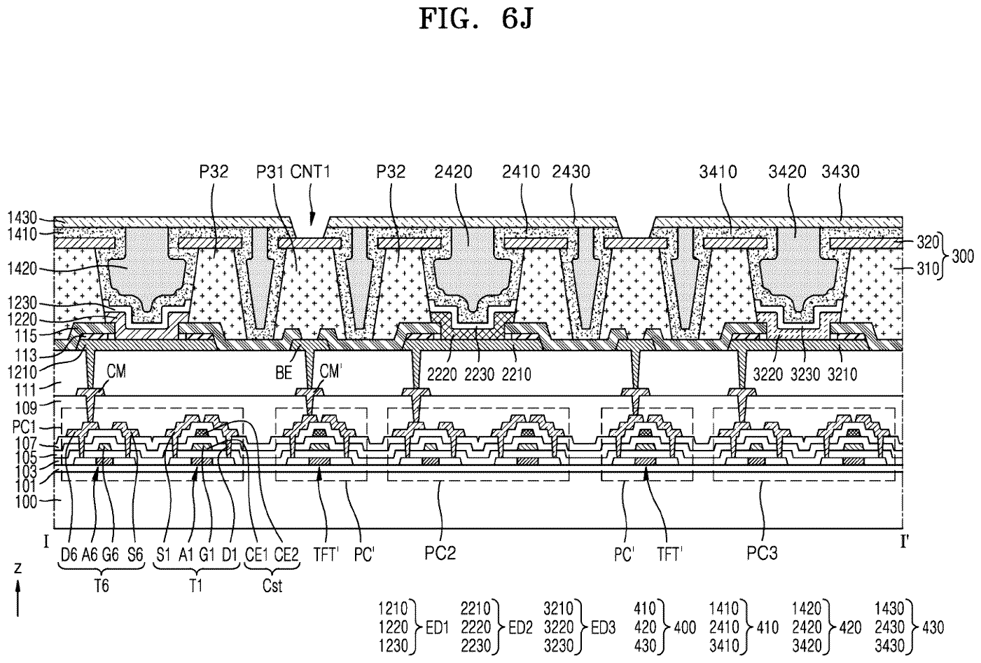

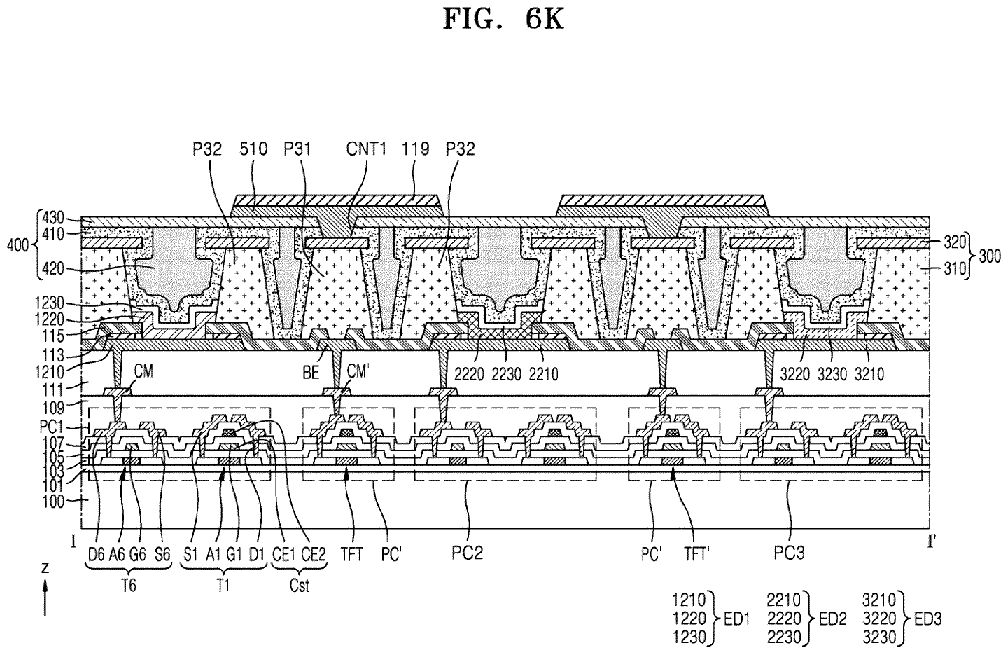

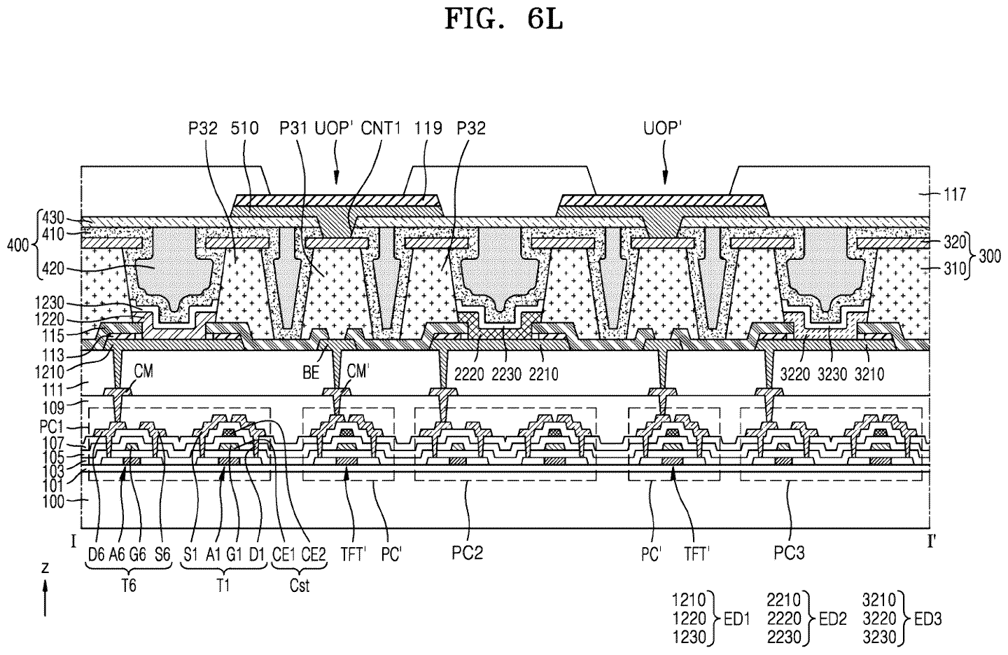

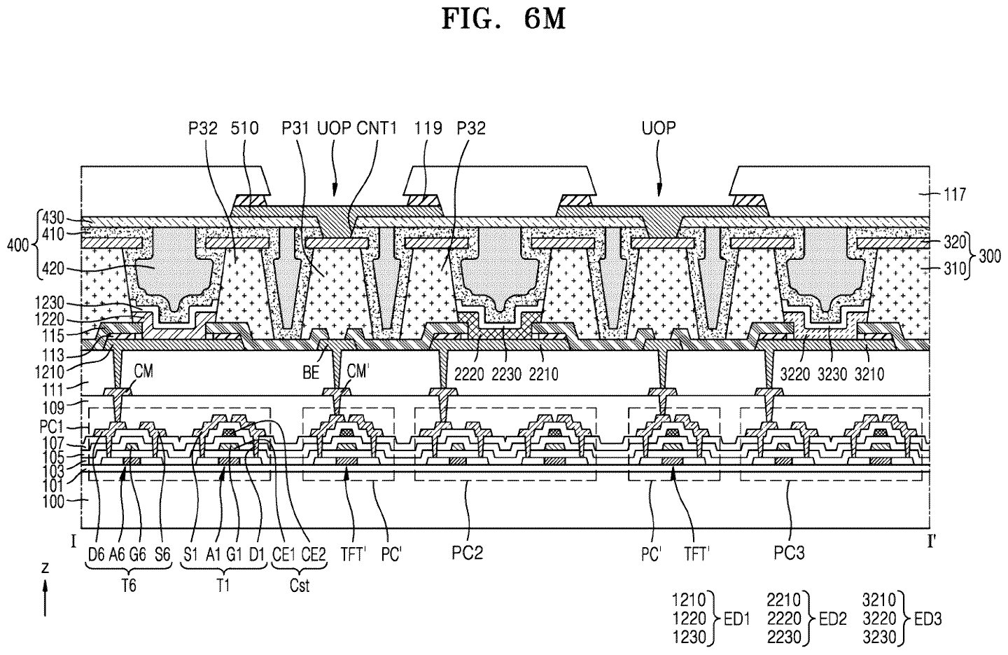

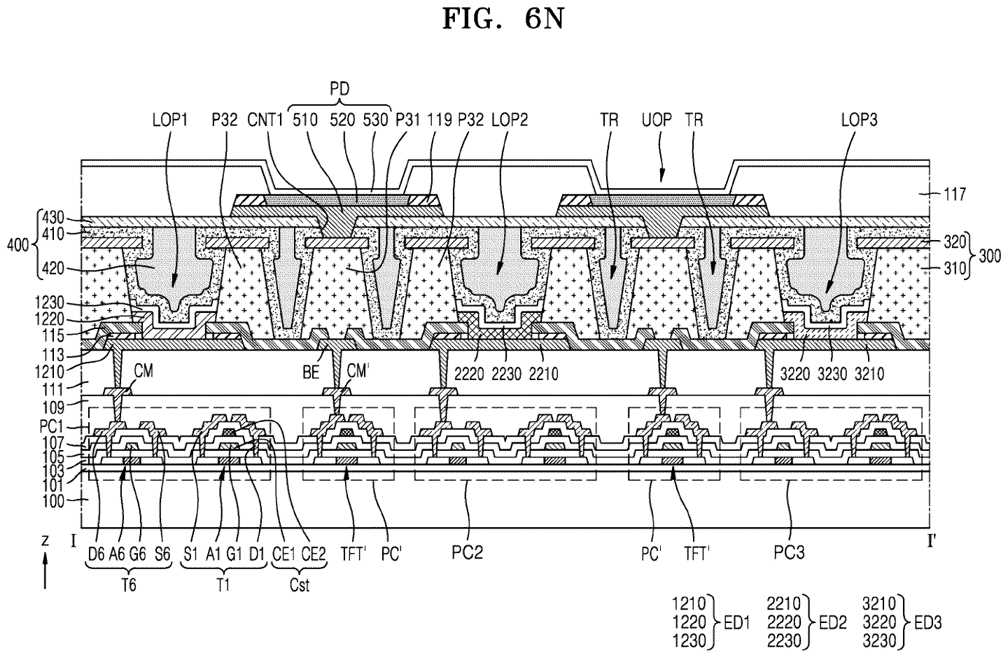

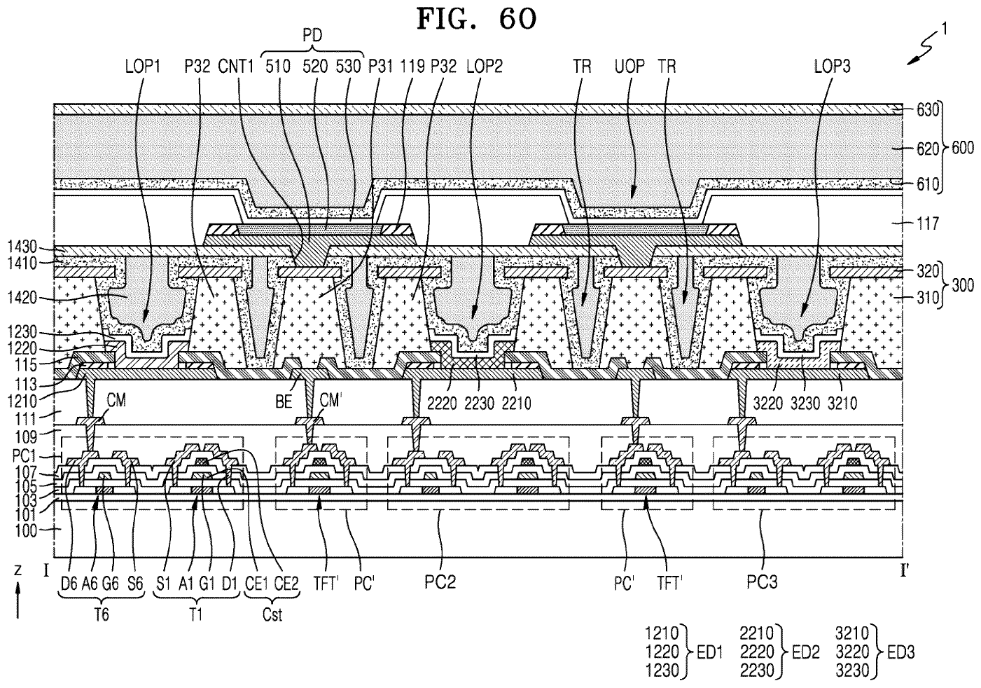

FIGS. 6A-6O are cross-sectional views schematically showing states according to a process of manufacturing a display apparatus according to one or more embodiments.

First, referring to FIG. 6A, first to third pixel electrodes 1210, 2210, and 3210 and a bridge electrode BE may be formed on a substrate 100. The first to third pixel electrodes 1210, 2210, and 3210 may be arranged for each pixel and spaced from each other. The bridge electrode BE may be arranged between pixel electrodes arranged adjacent to each other. The first to third pixel electrodes 1210, 2210, and 3210 and the bridge electrode BE may be formed together in the same process. The first to third pixel electrodes 1210, 2210, and 3210 and the bridge electrode BE may include the same material.

Before the first to third pixel electrodes 1210, 2210, and 3210 and the bridge electrode BE are formed, first to third light-emitting driving circuits PC1, PC2, and PC3, a sensing driving circuit PC′, and connection metals CM and CM′ may be formed between the substrate 100 and the first to third pixel electrodes 1210, 2210, and 3210.

Each of the first to third pixel electrodes 1210, 2210, and 3210 may include a reflective layer including Ag, Mg, Al, Pt, Pd, Au, Ni, Nd, Ir, Cr, and/or a compound thereof, and a transparent conductive layer including ITO, IZO, ZnO, and/or In₂O₃. In one or more embodiments, each of the first to third pixel electrodes 1210, 2210, and 3210 may have a structure in which an ITO layer, an Ag layer, and an ITO layer are sequentially stacked.

The first protective layer 113 may be formed to overlap each of the first to third pixel electrodes 1210, 2210, and 3210. The first protective layer 113 may include a conductive oxide, such as ITO, IZO, IGZO, ITZO, ZnO, AZO, GZO, ZTO, GTO, and/or FTO. The first protective layer 113 and the first to third pixel electrodes 1210, 2210, and 3210 may be patterned together in the same process.

An insulating layer 115 may be formed on the first protective layer 113. The insulating layer 115 may be integrally formed as one body over the entire surface of the substrate 100. Accordingly, the insulating layer 115 may cover not only the first protective layer 113 and the bridge electrode BE but also the exposed upper surface of the second organic insulating layer 111. The material of the insulating layer 115 is the same as previously described with reference to FIG. 5.

Material layers corresponding to the lower bank layer 300, for example, a first conductive layer 310 and a second conductive layer 320 on the first conductive layer 310, may be formed on the insulating layer 115. Characteristics such as the material and thickness of the first conductive layer 310 and the second conductive layer 320 are the same as previously described with reference to FIG. 5. For example, the thickness of the first conductive layer 310 may be greater than the thickness of the second conductive layer 320.

Next, referring to FIG. 6B, first to third lower openings LOP1, LOP2, and LOP3 and a trench TR may be formed in the lower bank layer 300. The first to third lower openings LOP1, LOP2, and LOP3 may overlap each pixel electrode 210, and the trench TR may be formed between lower openings disposed adjacent to each other.

The first to third lower openings LOP1, LOP2, and LOP3 and the trench TR may be formed through an etching process. Specifically, photoresist may be formed, on the second conductive layer 320, in the remaining areas excluding the areas where the first to third lower openings LOP1, LOP2, and LOP3 and the trench TR will be formed. Using the photoresist as a mask, portions of the first conductive layer 310 and the second conductive layer 320 may be removed to form the first to third lower openings LOP1, LOP2, and LOP3 and the trench TR. The first to third lower openings LOP1, LOP2, and LOP3 may have the shapes of through-holes passing through the lower bank layer 300 and the insulating layer 115. The process of removing portions of the lower bank layer 300 and the insulating layer 115 may be performed through dry etching.

In addition, because the first conductive layer 310 and the second conductive layer 320 of the lower bank layer 300 have different etch selectivity, even though the same etching process is performed, the first conductive layer 310 may be etched more than the second conductive layer 320. Accordingly, the second conductive layer 320 may include a tip that protrudes more toward a lower opening than the first conductive layer 310, and each of the first to third lower openings LOP1, LOP2, and LOP3 may have an undercut structure. The process of removing a portion of the first conductive layer 310 and a portion of the first protective layer 113 may be performed through wet etching.

By forming the trench TR in the lower bank layer 300, the lower bank layer 300 may be divided into a first portion P31 and a second portion P32. The second portion P32 may be a portion including a side of the lower bank layer 300 facing the first to third lower openings LOP1, LOP2, and LOP3, and the first portion P31 may have an island shape that is around (e.g., that is surrounded by) the second portion P32 in a plan view. The first portion P31 and the second portion P32 may be spaced from each other with the trench TR therebetween, the first portion P31 may be electrically connected to the light-receiving element PD, and the second portion P32 may be electrically connected to the light-emitting element ED.

Next, referring to FIG. 6C, an emission layer 220 (see FIG. 5) and an opposite electrode 230 (see FIG. 5) may be formed in the first to third lower openings LOP1, LOP2, and LOP3. The emission layer 220 (see FIG. 5) may include a first emission layer 1220 arranged in the first lower opening LOP1, a second emission layer 2220 arranged in the second lower opening LOP2, and a third emission layer 3220 arranged in the third lower opening LOP3. The opposite electrode 230 (see FIG. 5) may include a first opposite electrode 1230 disposed on the first emission layer 1220, a second opposite electrode 2230 disposed on the second emission layer 2220, and a third opposite electrode 3230 disposed on the third emission layer 3220.

The first to third emission layers 1220, 2220, and 3220 may be formed through a deposition method, such as thermal evaporation. The first to third emission layers 1220, 2220, and 3220 may be patterned and deposited in the first to third lower openings LOP1, LOP2, and LOP3 by the undercut structure of the lower bank layer 300 without a separate mask. Similarly, the first to third opposite electrodes 1230, 2230, and 3230 may be formed through a deposition method, such as thermal evaporation. The first to third opposite electrodes 1230, 2230, and 3230 may be deposited as patterned in the first to third lower openings LOP1, LOP2, and LOP3 by the undercut structure of the lower bank layer 300 without a separate mask. However, during a deposition process, the incident angle of a material forming the opposite electrode 230 (see FIG. 5) may be different from the incident angle of a material forming the emission layer 220 (see FIG. 5). Accordingly, the first to third opposite electrodes 1230, 2230, and 3230 may be deposited so that outer portions thereof directly contact the side of the first conductive layer 310.

Next, referring to FIG. 6D, the first lower inorganic encapsulation layer 410 may be formed on the structure shown in FIG. 6C. The first lower inorganic encapsulation layer 410 may include one or more inorganic materials selected from the group consisting of aluminum oxide, titanium oxide, tantalum oxide, hafnium oxide, zinc oxide, silicon oxide, silicon nitride, and/or silicon oxynitride, and may be deposited using a chemical vapor deposition method. The first lower inorganic encapsulation layer 410, which has excellent step coverage, may continuously cover the inner surfaces of the first to third lower openings LOP1, LOP2, and LOP3 and the inner surface of the trench TR.

The reliability of the display apparatus 1 may be evaluated by evaluating the structure shown in FIG. 6D at room temperature, high temperature, and high humidity. Because, in the structure shown in FIG. 6D, the light-emitting element ED is covered with the first lower inorganic encapsulation layer 410, environmental reliability evaluation may be performed to check whether there are any unusual issues in the process performed to date. When environmental reliability evaluation is performed at an intermediate stage like this, it is possible to check whether the process may proceed further, thereby avoiding sending defective products to a following process, thereby increasing yield and reducing costs.

Next, referring to FIG. 6E, a lower organic encapsulation layer 420 may be formed in the first to third lower openings LOP1, LOP2, and LOP3. The lower organic encapsulation layer 420 may be arranged not only in the first to third lower openings LOP1, LOP2, and LOP3 but also in the trench TR, and thus may flatten the upper surface of the display apparatus 1. The material of the lower organic encapsulation layer 420 is the same as previously described with reference to FIG. 5.

Thereafter, a hard mask HM and a mask protection layer MP may be formed on the first lower inorganic encapsulation layer 410 and the lower organic encapsulation layer 420. The hard mask HM may be formed on an area not including a portion of the upper surface of the first portion P31 of the lower bank layer 300. That is, the hard masks HM may be arranged to be spaced from each other with a portion of the upper surface of the first portion P31 therebetween. Unlike photoresist, the hard mask HM may include a metal, such as chromium (Cr). In addition, compared to the photoresist, the hard mask HM may include a relatively hard metal material, and thus, when the hard mask HM is used as a mask layer for forming small-diameter holes, pattern formation is possible without using high-resolution semiconductor equipment. Accordingly, the manufacturing process may be facilitated by using the hard mask HM to form a small hole in the first lower inorganic encapsulation layer 410.

However, in order to prevent damage to an underlying structure during an etching process for the first lower inorganic encapsulation layer 410, the mask protection layer MP may be formed under the hard mask HM. The mask protection layer MP may be deposited to overlap the hard mask HM. Like the hard mask HM, the mask protection layer MP may be formed on an area not including a portion of the upper surface of the first portion P31 of the lower bank layer 300. The mask protection layer MP may include the same material as the first protective layer 113. For example, the mask protection layer MP may include a conductive oxide, such as ITO, IZO, IGZO, ITZO, ZnO, AZO, GZO, ZTO, GTO, and/or FTO.

Next, referring to FIG. 6F, a portion of the first lower inorganic encapsulation layer 410 may be etched using the hard mask HM. Because the hard mask HM is not arranged on a part of the first portion P31 of the lower bank layer 300, when a dry etching process is performed, a portion of the first lower inorganic encapsulation layer 410, which does not overlap the hard mask HM, may be etched. That is, a hole H′ may be formed in a portion of the first lower inorganic encapsulation layer 410, which overlaps the first portion P31, and the hole H′ may be a preliminary contact hole connecting the light-receiving element PD (see FIG. 5) to the lower bank layer 300.

In addition, as the hole H′ is formed in the first lower inorganic encapsulation layer 410, the first lower inorganic encapsulation layer 410 may be divided into a 1st-1 lower inorganic encapsulation layer 1410, a 1st-2 lower inorganic encapsulation layer 2410, and a 1st-3 lower inorganic encapsulation layer 3410. The 1st-1 lower inorganic encapsulation layer 1410, the 1st-2 lower inorganic encapsulation layer 2410, and the 1st-3 lower inorganic encapsulation layer 3410 may be arranged to be spaced from each other with the hole H′ therebetween.

Next, referring to FIG. 6G, the hard mask HM and the mask protection layer MP may be removed, and a second lower inorganic encapsulation layer 430 may be formed on the first lower inorganic encapsulation layer 410 and the lower organic encapsulation layer 420. The second lower inorganic encapsulation layer 430 may include one or more inorganic materials selected from the group consisting of aluminum oxide, titanium oxide, tantalum oxide, hafnium oxide, zinc oxide, silicon oxide, silicon nitride, and silicon oxynitride, and may be deposited using a chemical vapor deposition method. The second lower inorganic encapsulation layer 430 may be integrally formed as one body over the entire surface of the substrate 100.

Next, referring to FIG. 6H, a hard mask HM and a mask protection layer MP may be formed on the second lower inorganic encapsulation layer 430. The material of each of the hard mask HM and the mask protection layer MP is the same as described with reference to FIG. 6E. The hard mask HM and the mask protection layer MP may be formed on an area not including a portion of the upper surface of the first portion P31 of the lower bank layer 300. That is, the hard mask HM and the mask protection layer MP may be arranged to be spaced from each other with a portion of the upper surface of the first portion P31 therebetween. An area where the hard mask HM and the mask protection layer MP are not formed may overlap an area where the hole H′ of the first lower inorganic encapsulation layer 410 is formed in FIG. 6F.

Next, referring to FIG. 61, a portion of the second lower inorganic encapsulation layer 430 may be etched using the hard mask HM. Through a dry etching process, a portion of the second lower inorganic encapsulation layer 430, which does not overlap the hard mask HM, may be etched. A hole H″ may be formed in a portion of the second lower inorganic encapsulation layer 430, which overlaps the first portion P31, and the hole H″ may be a preliminary contact hole connecting the light-receiving element PD (see FIG. 5) to the lower bank layer 300.

Next, referring to FIG. 6J, the hard mask HM and the mask protection layer MP, formed on the second lower inorganic encapsulation layer 430, may be removed. The hard mask HM and the mask protection layer MP may be removed through an etching process.

The hole H′ (see FIG. 6F) formed in a portion of the first lower inorganic encapsulation layer 410, which overlaps the first portion P31, may overlap the hole H″ (see FIG. 6I) formed in a portion of the second lower inorganic encapsulation layer 430, which overlaps the first portion P31. That is, a contact hole CNT1 may be formed in portions of the first lower inorganic encapsulation layer 410 and the second lower inorganic encapsulation layer 430, which overlap the first portion P31, and thus, a portion of the upper surface of the first portion P31 may be exposed. As described above, the contact hole CNT1 may be formed to connect the light-receiving element PD (see FIG. 5) to the sensing driving circuit PC′.

Next, referring to FIG. 6K, a sensing electrode 510 and a second protective layer 119 may be formed on a lower encapsulation layer 400. Sensing electrodes 510 may be arranged in a non-emission area and may be spaced from each other. The sensing electrode 510 may include the same material as the pixel electrode 210. In one or more embodiments, the sensing electrode 510 may have a structure in which an ITO layer, an Ag layer, and/or an ITO layer are sequentially stacked.

The second protective layer 119 may overlap the sensing electrode 510. The second protective layer 119 may include the same material as the first protective layer 113. The second protective layer 119 may include a conductive oxide, such as ITO, IZO, IGZO, ITZO, ZnO, AZO, GZO, ZTO, GTO, and/or FTO. The second protective layer 119 and the sensing electrode 510 may be patterned together in the same process.

Next, referring to FIG. 6L, an upper bank layer 117 may be formed on the sensing electrode 510 and the second protective layer 119. The material of the upper bank layer 117 is the same as described with reference to FIG. 5. The upper bank layer 117 may be patterned to include an opening that overlaps the sensing electrode 510. Specifically, the upper bank layer 117 may overlap the sensing electrode 510 and include a preliminary upper opening UOP′ exposing a central portion of the upper surface of the second protective layer 119.

Next, referring to FIG. 6M, a portion of the second protective layer 119 may be etched to expose a central portion of the sensing electrode 510. The process of removing the portion of the second protective layer 119 may be performed through wet etching. As a portion of the second protective layer 119 overlapping the central portion of the sensing electrode 510 is removed, an upper opening UOP may be formed.

Next, referring to FIG. 6N, an active layer 520 and a sensing opposite electrode 530 may be formed in the upper opening UOP. The active layer 520 may be formed through a deposition method, such as thermal evaporation. The active layer 520 may be patterned and formed to be deposited within the upper opening UOP.

Similarly, the sensing opposite electrode 530 may be formed through a deposition method, such as thermal evaporation. However, the sensing opposite electrode 530 may be deposited not only within the upper opening UOP but also on the upper bank layer 117. That is, the sensing opposite electrode 530 may be integrally formed as one body over the entire surface of the substrate 100. The material of each of the active layer 520 and the sensing opposite electrode 530 is the same as described with reference to FIG. 5.

Next, referring to FIG. 6O, an upper encapsulation layer 600 may be formed on the structure shown in FIG. 6N. The upper encapsulation layer 600 may include a first upper inorganic encapsulation layer 610, an upper organic encapsulation layer 620 on the first upper inorganic encapsulation layer 610, and a second upper inorganic encapsulation layer 630 on the upper organic encapsulation layer 620.

The first upper inorganic encapsulation layer 610 may be formed on the sensing opposite electrode 530 and integrally formed as one body over the entire surface of the substrate 100. Because the first upper inorganic encapsulation layer 610 has excellent step coverage, the first upper inorganic encapsulation layer 610 may extend to cover the inner surface of the upper opening UOP. The upper organic encapsulation layer 620 may not only fill the upper opening UOP but also may be disposed above the upper bank layer 117 to flatten the upper surface of the display apparatus 1. The second upper inorganic encapsulation layer 630 may be formed on the upper organic encapsulation layer 620 and integrally formed as one body over the entire surface of the substrate 100. That is, the first upper inorganic encapsulation layer 610 and the second upper inorganic encapsulation layer 630 may be arranged to be spaced from each other with the upper organic encapsulation layer 620 therebetween.

In one or more embodiments, the first upper inorganic encapsulation layer 610 may include the same material as the first lower inorganic encapsulation layer 410, the upper organic encapsulation layer 620 may include the same material as the lower organic encapsulation layer 420, and the second upper inorganic encapsulation layer 630 may include the same material as the second lower inorganic encapsulation layer 430. However, the present disclosure is not limited thereto, and the upper encapsulation layer 600 may include a different material from the lower encapsulation layer 400.

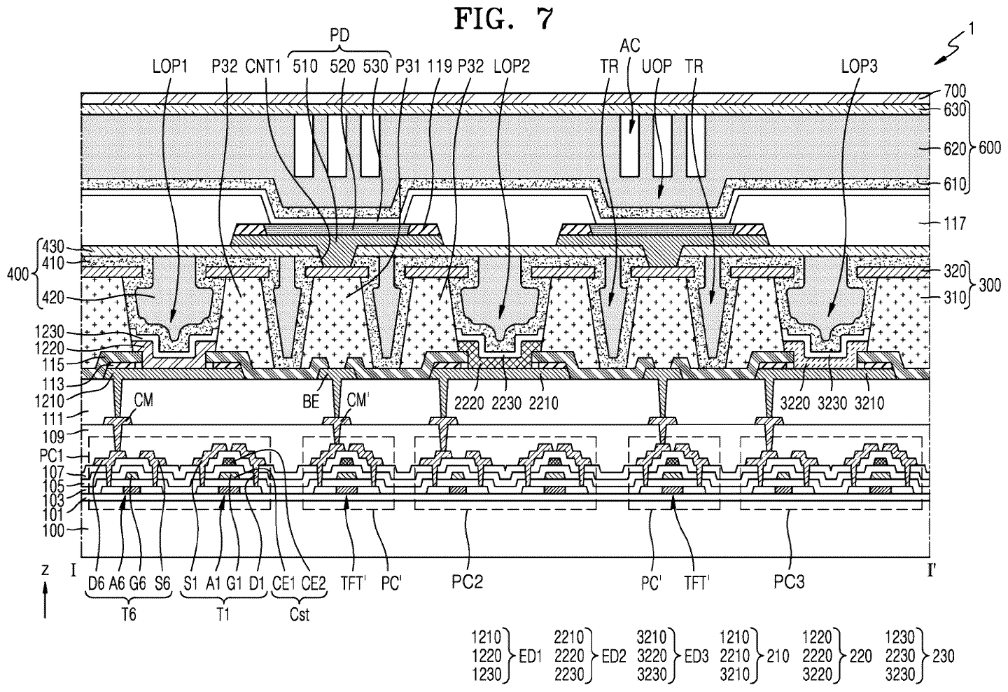

FIG. 7 is a schematic cross-sectional view of a portion of a display apparatus 1 taken along the line I-I′ of FIG. 4, according to one or more embodiments. Referring to FIG. 7, except for the features of the upper organic encapsulation layer 620, other features are the same as those described with reference to FIG. 5. In FIG. 7, the same reference numerals as those in FIG. 5 denote the same members as those in FIG. 5, and thus, the differences will be mainly described below.

Referring to FIG. 7, a plurality of air cavities AC may be formed in the upper organic encapsulation layer 620. The plurality of air cavities AC are air gaps formed in the upper organic encapsulation layer 620 and may have a tunnel shape extending in a direction perpendicular to the substrate 100. The plurality of air cavities AC may overlap the sensing electrode 510 of the light-receiving element PD.

An input sensing layer 700 may be disposed on the upper encapsulation layer 600, and parasitic capacitance due to the light-receiving element PD, which is a lower structure closest to the input sensing layer 700, may be formed in the input sensing layer 700. However, the dielectric constant of the upper organic encapsulation layer 620 has a value of about 3.0 to about 3.2 and the dielectric constant of the air cavity has a value of about 1.0, and thus, when a plurality of air cavities AC are formed in the upper organic encapsulation layer 620, the density of the upper organic encapsulation layer 620 may be reduced. Accordingly, the parasitic capacitance caused by the light-receiving element PD formed in the input sensing layer 700 may be reduced, and thus, the touch sensitivity of a touch electrode included in the input sensing layer 700 may be efficiently improved. That is, the display apparatus 1 according to one or more embodiments may not only increase resolution by placing the light-receiving element PD on a different layer from the light-emitting element ED, but also may improve the touch sensitivity of the input sensing layer 700.

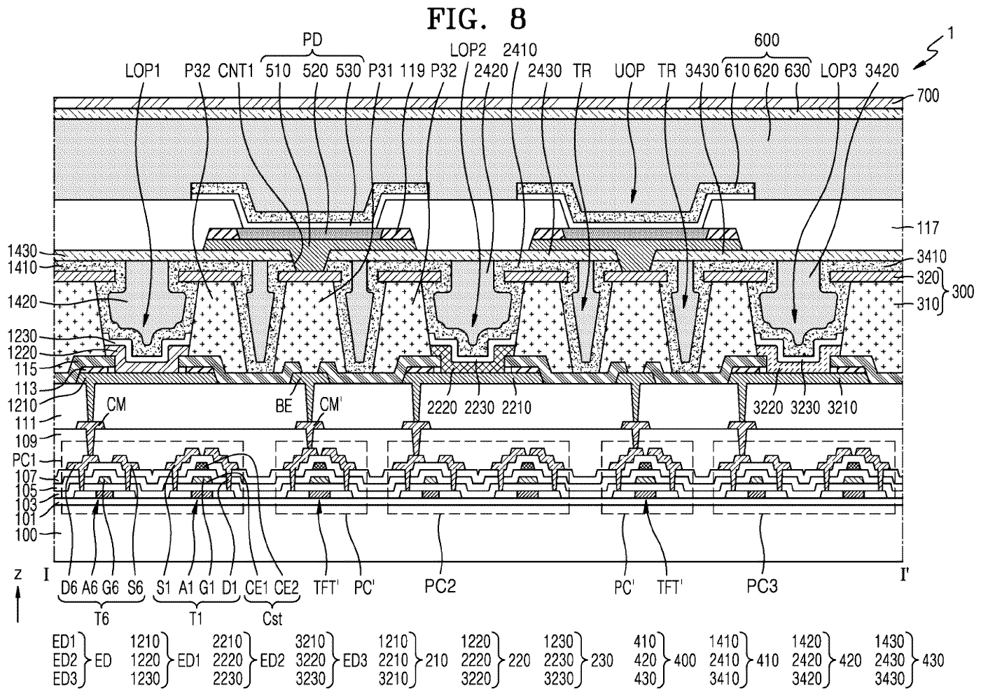

FIG. 8 is a schematic cross-sectional view of a portion of a display apparatus 1 taken along the line I-I′ of FIG. 4, according to one or more embodiments. Referring to FIG. 8, except for the features of the sensing opposite electrode 530 and the upper encapsulation layer 600, other features are the same as those described with reference to FIG. 5. In FIG. 8, the same reference numerals as those in FIG. 5 denote the same members as those in FIG. 5, and thus, the differences will be mainly described below.

Referring to FIG. 8, the sensing opposite electrode 530 may not only be arranged in the upper opening UOP, but may also be disposed on the upper bank layer 117. However, the sensing opposite electrode 530 may not be integrally formed as one body over the entire surface of the substrate 100, but a plurality of sensing opposite electrodes 530 may be arranged to be spaced from each other. That is, the sensing opposite electrode 530 may be individually disposed for each of the plurality of light-receiving elements PD.

The first upper inorganic encapsulation layer 610 may be disposed on the sensing opposite electrode 530. The first upper inorganic encapsulation layer 610, which has excellent step coverage, may cover at least a portion of the inner surface of the upper opening UOP. The first upper inorganic encapsulation layer 610 may be continuously formed to overlap the upper and side surfaces of the upper bank layer 117 and the upper surface of the sensing opposite electrode 530. However, like the sensing opposite electrode 530, a plurality of first upper inorganic encapsulation layers 610 may be arranged to be spaced from each other. Specifically, the first upper inorganic encapsulation layers 610 may be respectively arranged to encapsulate each of the plurality of light-receiving elements PD while being arranged to be spaced from each other

The upper organic encapsulation layer 620 may be disposed on the first upper inorganic encapsulation layer 610 to flatten the upper surface of the display apparatus 1. Accordingly, the upper organic encapsulation layer 620 may cover the upper surface of the upper bank layer 117 that is exposed due to the absence of the sensing opposite electrode 530 and the first upper inorganic encapsulation layer 610.

In the upper encapsulation layer 600 having the above structure, because the plurality of first upper inorganic encapsulation layers 610 are arranged to be spaced from each other, a structure in which each light-receiving element PD is sealed for each device unit may be formed. Because the upper encapsulation layer 600 may seal each light-receiving element PD, even when a defect, such as a dark spot, occurs due to penetration of contaminants from the outside, the effect of suppressing the growth of the defect may be provided. Accordingly, the display apparatus 1 according to one or more embodiments may not only improve resolution by the arrangement of the light-emitting element ED and the light-receiving element PD on different layers, but also may produce images of excellent quality by the sealing of both the light-emitting element ED and the light-receiving element PD for each device unit.

The display apparatus according to one or more embodiments as described above may improve resolution by the arrangement of a light-emitting element and a light-receiving element on different layers. The aforementioned effects are examples, and the scope of the present disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A display apparatus comprising:
a substrate including an emission area and a sensing area;
a light-emitting element on the substrate and overlapping the emission area;
a lower bank layer having a lower opening defining the emission area, the lower bank layer comprising a first conductive layer and a second conductive layer on the first conductive layer;
a light-receiving element on the lower bank layer and overlapping the sensing area; and
an upper bank layer including an upper opening defining the sensing area,
wherein the light-emitting element and the light-receiving element are located at different layers.

2. The display apparatus of claim 1, wherein the light-emitting element comprises:
a pixel electrode in the emission area;
an emission layer in the lower opening of the lower bank layer and overlapping the pixel electrode; and
an opposite electrode in the lower opening of the lower bank layer and overlapping the emission layer.

3. The display apparatus of claim 1, wherein the light-receiving element comprises:
a sensing electrode in the sensing area;
an active layer in the upper opening of the upper bank layer and overlapping the sensing electrode; and
a sensing opposite electrode on the active layer and an entire surface of the substrate.

4. The display apparatus of claim 1, wherein the light-emitting element and the upper bank layer overlap each other, and the light-receiving element and the lower bank layer overlap each other.

5. The display apparatus of claim 1, wherein the second conductive layer comprises a tip extending toward the lower opening from a point where a bottom surface of the second conductive layer and a side surface of the first conductive layer contact each other.

6. The display apparatus of claim 1, wherein the lower bank layer further includes a trench between lower openings adjacent to each other.

7. The display apparatus of claim 6, wherein the lower bank layer comprises a first portion and a second portion that are spaced from each other with the trench therebetween,
wherein the first portion and the second portion are electrically disconnected from each other.

8. The display apparatus of claim 7, wherein the second portion comprises a side of the lower bank layer facing the lower opening, and the first portion is located between second portions facing different lower openings.

9. The display apparatus of claim 8, wherein the second portion is around the first portion in a plan view, and the first portion has an island shape.

10. The display apparatus of claim 7, wherein the first portion is electrically connected to the light-receiving element, and the second portion is electrically connected to the light-emitting element.

11. The display apparatus of claim 7, wherein an opposite electrode of the light-emitting element directly contacts a side surface of the second portion facing the lower opening.

12. The display apparatus of claim 7, further comprising:
an emission driving circuit electrically connected to the light-emitting element; and
a sensing driving circuit electrically connected to the light-receiving element,
wherein the emission driving circuit and the sensing driving circuit are driven independently of each other.

13. The display apparatus of claim 12, wherein the sensing driving circuit and the light-receiving element are electrically connected to each other through the first portion.

14. The display apparatus of claim 13, further comprising a bridge electrode between the sensing driving circuit and the lower bank layer,
wherein a lower surface of the first conductive layer of the first portion is in contact with the bridge electrode, and an upper surface of the second conductive layer of the first portion is in contact with a sensing electrode of the light-receiving element.

15. The display apparatus of claim 14, wherein the bridge electrode is located at a same layer as a pixel electrode of the light-emitting element and comprises a same material as the pixel electrode.

16. The display apparatus of claim 1, further comprising:
a lower encapsulation layer covering the light-emitting element; and
an upper encapsulation layer covering the light-receiving element,
wherein the lower encapsulation layer and the upper encapsulation layer are located at different layers.

17. The display apparatus of claim 16, wherein the lower encapsulation layer encapsulates the light-emitting element and comprises a plurality of encapsulation layer units that are spaced from each other.

18. The display apparatus of claim 17, wherein each of the plurality of encapsulation layer units comprises:
a first lower inorganic encapsulation layer on the light-emitting element and extending to cover the lower opening;
a lower organic encapsulation layer on the first lower inorganic encapsulation layer and filling the lower opening; and
a second lower inorganic encapsulation layer on the lower organic encapsulation layer.

19. The display apparatus of claim 18, wherein the first lower inorganic encapsulation layer and the second lower inorganic encapsulation layer are in contact with each other on the lower bank layer.

20. The display apparatus of claim 16, wherein the upper encapsulation layer comprises:
a first upper inorganic encapsulation layer on the light-receiving element and extending to cover the upper opening;
an upper organic encapsulation layer on the first upper inorganic encapsulation layer; and
a second upper inorganic encapsulation layer on the upper organic encapsulation layer.

21. The display apparatus of claim 20, wherein the first upper inorganic encapsulation layer and the second upper inorganic encapsulation layer are spaced from each other with the upper organic encapsulation layer therebetween.

22. The display apparatus of claim 20, wherein the first upper inorganic encapsulation layer is integrally formed as one body over an entire surface of the substrate.

23. The display apparatus of claim 20, wherein the first upper inorganic encapsulation layer encapsulates each of a plurality of light-receiving elements, and a plurality of first upper inorganic encapsulation layers are spaced from each other.

24. The display apparatus of claim 20, wherein the upper organic encapsulation layer comprises a plurality of air cavities,
wherein the plurality of air cavities overlaps the light-receiving element.

25. A method of manufacturing a display apparatus, the method comprising:
forming a pixel electrode on a substrate;
forming a lower bank layer on the pixel electrode, the lower bank layer comprises a first conductive layer and a second conductive layer on the first conductive layer;
forming, in the lower bank layer, a lower opening overlapping the pixel electrode;
forming, in the lower opening of the lower bank layer, an emission layer overlapping the pixel electrode;
forming, in the lower opening of the lower bank layer, an opposite electrode overlapping the emission layer;
forming a sensing electrode on the lower bank layer;
forming an upper bank layer on the sensing electrode;
forming, in the upper bank layer, an upper opening overlapping the sensing electrode;
forming an active layer arranged in the upper opening of the upper bank layer and overlapping the sensing electrode; and
forming a sensing opposite electrode on the upper bank layer and the active layer.

26. The method of claim 25, further comprising forming, in the lower bank layer, a trench between lower openings arranged adjacent to each other,
wherein the trench is formed through a same etching process as the lower opening.

27. The method of claim 26, wherein the lower bank layer comprises a first portion and a second portion that are spaced from each other with the trench therebetween,
wherein the first portion is in contact with the sensing electrode, and the second portion is in contact with the opposite electrode.

28. The method of claim 25, further comprising forming a lower encapsulation layer between the forming of the opposite electrode and the forming of the sensing electrode,
wherein the forming of the lower encapsulation layer comprises:
forming a first lower inorganic encapsulation layer on the opposite electrode and the lower bank layer;
forming a lower organic encapsulation layer on the first lower inorganic encapsulation layer to fill the lower opening; and
forming a second lower inorganic encapsulation layer on the lower organic encapsulation layer.

29. The method of claim 28, further comprising:
between the forming of the lower organic encapsulation layer and the forming of the second lower inorganic encapsulation layer, etching a portion of the first lower inorganic encapsulation layer on the lower bank layer; and
between the forming of the second lower inorganic encapsulation layer and the forming of the sensing electrode, etching a portion of the second lower inorganic encapsulation layer on the lower bank layer.

30. The method of claim 29, wherein the sensing electrode is electrically connected to the lower bank layer through a contact hole formed by etching a portion of each of the first lower inorganic encapsulation layer and the second lower inorganic encapsulation layer.

31. The method of claim 25, further comprising: after the forming of the sensing opposite electrode, forming an upper encapsulation layer,
wherein the forming of the upper encapsulation layer comprises:
forming a first upper inorganic encapsulation layer over an entire surface of the substrate on the sensing opposite electrode;
forming an upper organic encapsulation layer on the first upper inorganic encapsulation layer, filling the upper opening, and on the upper bank layer; and
forming a second upper inorganic encapsulation layer on the upper organic encapsulation layer.

32. The method of claim 31, further comprising: between the forming of the upper organic encapsulation layer and the forming of the second upper inorganic encapsulation layer, forming a plurality of air cavities in the upper organic encapsulation layer,
wherein the plurality of air cavities overlaps the sensing electrode.

33. The method of claim 25, further comprising: before the forming of the pixel electrode,
forming an emission driving circuit electrically connected to a light-emitting element comprising the pixel electrode, the emission layer, and the opposite electrode; and
forming a sensing driving circuit electrically connected to a light-receiving element including the sensing electrode, the active layer, and the sensing opposite electrode.

34. The method of claim 33, further comprising forming a bridge electrode between the sensing driving circuit and the lower bank layer,
wherein the bridge electrode is formed through a same deposition process as the pixel electrode.

35. The method of claim 34, wherein the sensing driving circuit is electrically connected to the sensing electrode through the bridge electrode and the lower bank layer.
